(19) United States
(12) Patent Application Publication
(10) Pub. No.: US 2024/0268101 A1
(43) Pub. Date: Aug. 8, 2024

(54) SEMICONDUCTOR DEVICE AND A METHOD OF MANUFACTURING THE SAME

(71) Applicant: Samsung Electronics Co., Ltd., Suwon-si (KR)

(72) Inventors: SangJae PARK, Suwon-si (KR); Seung-Bo KO, Suwon-si (KR); Keunnam KIM, Suwon-si (KR); Jongmin KIM, Suwon-si (KR); Hui-Jung KIM, Suwon-si (KR); Taejin PARK, Suwon-si (KR); Chan-Sic YOON, Suwon-si (KR); Kiseok LEE, Suwon-si (KR); Myeong-Dong LEE, Suwon-si (KR); Hongjun LEE, Suwon-si (KR)

(73) Assignee: Samsung Electronics Co., Ltd., Suwon-si (KR)

(21) Appl. No.: 18/471,900

(22) Filed: Sep. 21, 2023

(30) Foreign Application Priority Data
Feb. 2, 2023 (KR) 10-2023-0014375

(51) Int. Cl. H10B 12/00

(52) U.S. Cl. CPC H10B 12/482; H10B 12/05; H10B 12/34; H10B 12/485; H10B 12/488

(57) ABSTRACT

A semiconductor device includes first and second active patterns extending in a first direction and being adjacent to each other in a second direction, the first and second active patterns, each of which includes first and second edges spaced apart from each other in the first direction, a first storage node pad and a first storage node contact sequentially provided on the first edge of the first active pattern, a second storage node pad and a second storage node contact sequentially provided on the second edge of the second active pattern, and a fence pattern between the first and the second storage node contacts. Bottom and top surfaces of the first storage node contact are located at first and second levels, respectively. In a third direction, a width of the fence pattern at the first level is less than a width of the fence pattern at the second level.

### CROSS-REFERENCE TO RELATED APPLICATIONS

This U.S. non-provisional patent application claims priority under 35 U.S.C. § 119 to Korean Patent Application No. 10-2023-0014375, filed on Feb. 2, 2023, in the Korean Intellectual Property Office, the entire contents of which are hereby incorporated by reference.

### BACKGROUND OF THE INVENTION

The present disclosure relates to semiconductor devices and methods of manufacturing the same.

Semiconductor devices are widely used in an electronic industry because of their small sizes, multi-functional characteristics, and/or low manufacturing costs. Semiconductor devices may be categorized as any one of semiconductor memory devices for storing logical data, semiconductor logic devices for processing logical data, and hybrid semiconductor devices having both the function of the semiconductor memory devices and the function of the semiconductor logic devices.

High-speed and low-voltage semiconductor devices have been demanded to satisfy characteristics (e.g., high speed and/or low power consumption) of electronic devices including semiconductor devices. Semiconductor devices have been highly integrated to meet these demands. Thus, various techniques for improving the integration density of semiconductor devices have been studied.

### SUMMARY

Example embodiments of the inventive concepts may provide semiconductor devices capable of being manufactured, for example, more easily or having simpler manufacturing, and improving an integration density, and methods of manufacturing the same.

Example embodiments of the inventive concepts may also provide semiconductor devices with improved electrical characteristics and reliability, and methods of manufacturing the same.

In some aspects of the inventive concepts, a semiconductor device may include a first active pattern and a second active pattern which extend in a first direction and are adjacent to each other in a second direction intersecting the first direction, the first and second active patterns, each of which includes a first edge portion and a second edge portion spaced apart from each other in the first direction; a first storage node pad and a first storage node contact which are sequentially provided on the first edge portion of the first active pattern; a second storage node pad and a second storage node contact which are sequentially provided on the second edge portion of the second active pattern; and a fence pattern between the first storage node contact and the second storage node contact. A bottom surface and a top surface of the first storage node contact may be located at a first level and a second level, respectively. A width of the fence pattern in a third direction intersecting the first and second directions at the first level may be less than a width of the fence pattern in the third direction at the second level.

In some aspects of the inventive concepts, a semiconductor device may include a first active pattern and a second active pattern which extend in a first direction and are adjacent to each other in a second direction intersecting the first direction, the first and second active patterns, each of which includes a first edge portion and a second edge portion spaced apart from each other in the first direction; a pair of word lines extending in the second direction to intersect the first active pattern and the second active pattern; a first storage node pad and a first storage node contact which are sequentially provided on the first edge portion of the first active pattern; and a second storage node pad and a second storage node contact which are sequentially provided on the second edge portion of the second active pattern. The first storage node pad may include the same or substantially the same material as the first storage node contact.

In some aspects of the inventive concepts, a semiconductor device may include a first active pattern and a second active pattern which extend in a first direction and are adjacent to each other in a second direction intersecting the first direction, the first and second active patterns, each of which includes first and second edge portions spaced apart from each other in the first direction and a center portion between the first and second edge portions: a pair of word lines extending in the second direction to intersect the first active pattern and the second active pattern; a first storage node pad and a first storage node contact which are sequentially provided on the first edge portion of the first active pattern; a second storage node pad and a second storage node contact which are sequentially provided on the second edge portion of the second active pattern; a first bit line extending in a third direction intersecting the first and second directions on the first active pattern: a second bit line extending in the third direction on the second active pattern; a fence pattern between the first storage node contact and the second storage node contact: landing pads on the first storage node contact and the second storage node contact; and data storage patterns on the landing pads. A bottom surface and a top surface of the first storage node contact may be located at a first level and a second level, respectively. A width of the fence pattern in the third direction at the first level may be less than a width of the fence pattern in the third direction at the second level.

In some aspects of the inventive concepts, a method of manufacturing a semiconductor device may include forming a first active pattern, a second active pattern, and a device isolation pattern surrounding each of the first and second active patterns in a plan view, the first and second active patterns extending in a first direction and being adjacent to each other in a second direction intersecting the first direction, and the first and second active patterns, each of which includes a first edge portion and a second edge portion spaced apart from each other in the first direction; forming a first storage node pad on the first edge portion of the first active pattern and a second storage node pad on the second edge portion of the second active pattern: forming a first bit line extending in a third direction intersecting the first and second directions on the first active pattern and a second bit line extending in the third direction on the second active pattern: forming a storage node line extending in the third direction between the first and second bit lines; etching the storage node line to form a first storage node contact on the first storage node pad and a second storage node contact on the second storage node pad; and forming a fence pattern between the first storage node contact and the second storage node contact.

### BRIEF DESCRIPTION OF THE DRAWINGS

FIG. 1 is a plan view illustrating a semiconductor device according to some example embodiments of the inventive concepts.

FIG. 2 is an enlarged view of some components of FIG. 1.

FIGS. 3A, 3B, 3C and 3D are cross-sectional views corresponding to lines A-A′, B-B′, C-C′ and D-D′ of FIG. 1, respectively.

FIG. 4 is a plan view illustrating components provided below a second level of FIG. 3C in the semiconductor device of FIG. 1.

FIG. 5 is a plan view illustrating a semiconductor device according to some example embodiments of the inventive concepts.

FIGS. 6A and 6B are cross-sectional views corresponding to lines C-C′ and D-D′ of FIG. 5, respectively.

FIG. 7 is a plan view illustrating a semiconductor device according to some example embodiments of the inventive concepts.

FIGS. 8, 10 and 12 are plan views illustrating semiconductor devices according to some example embodiments of the inventive concepts.

FIGS. 9A, 9B, 9C and 9D are cross-sectional views corresponding to lines A-A′, B-B′, C-C′ and D-D′ of FIG. 8, respectively.

FIGS. 11A, 11B, 11C and 11D are cross-sectional views corresponding to lines A-A′, B-B′, C-C′ and D-D′ of FIG. 10, respectively.

FIGS. 13A, 13B, 13C and 13D are cross-sectional views corresponding to lines A-A′, B-B′, C-C′ and D-D′ of FIG. 12, respectively.

FIGS. 14 to 25D are views illustrating a method of manufacturing the semiconductor device of FIGS. 1 to 3D.

FIGS. 26 to 27B are views illustrating a method of manufacturing the semiconductor device of FIGS. 5 to 6B.

FIG. 28 is a plan view illustrating a method of manufacturing the semiconductor device of FIG. 7.

FIGS. 29 to 32D are views illustrating a method of manufacturing the semiconductor device of FIGS. 8 to 9D.

FIGS. 33 to 34D are views illustrating a method of manufacturing the semiconductor device of FIGS. 10 to 11D.

FIGS. 35 to 36D are views illustrating a method of manufacturing the semiconductor device of FIGS. 12 to 13D.

### DETAILED DESCRIPTION

Example embodiments of the inventive concepts will now be described more fully with reference to the accompanying drawings.

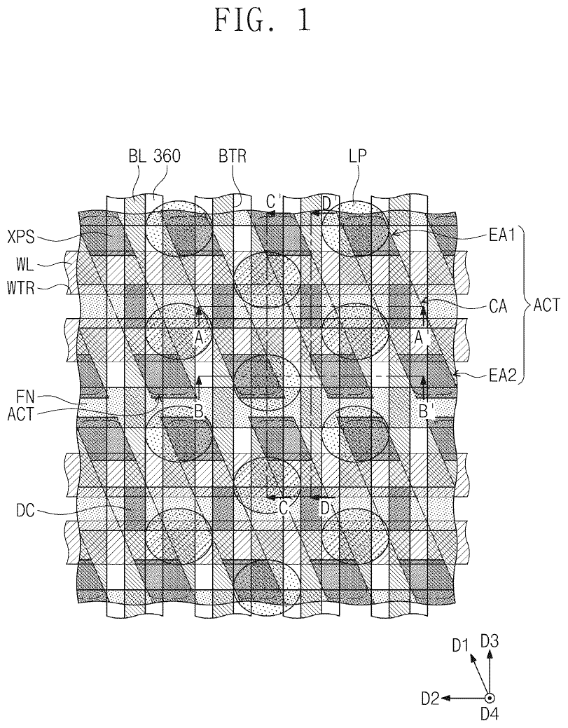

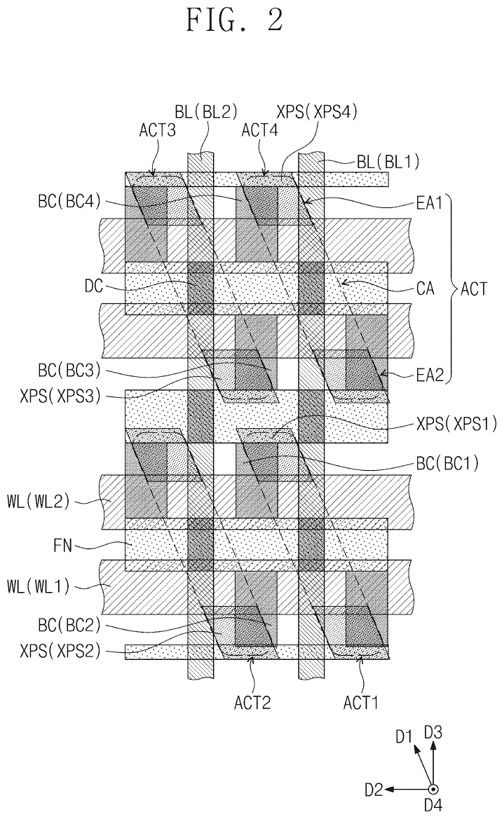

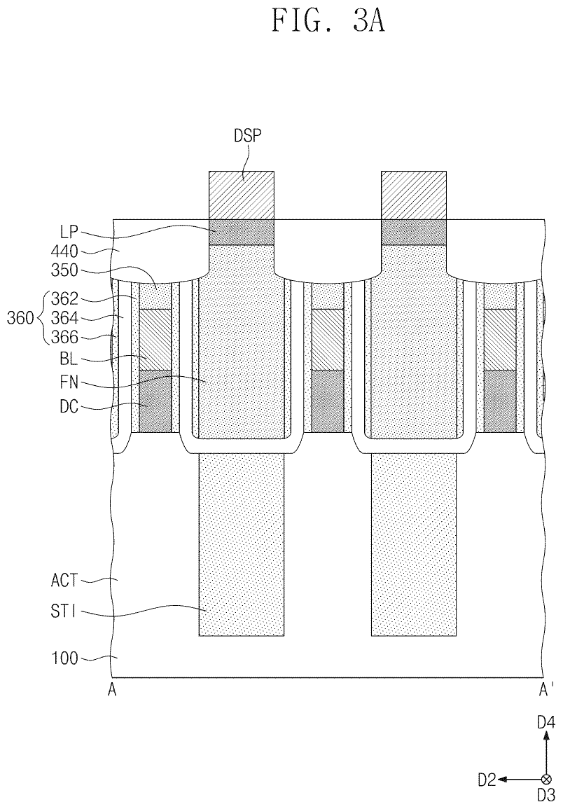

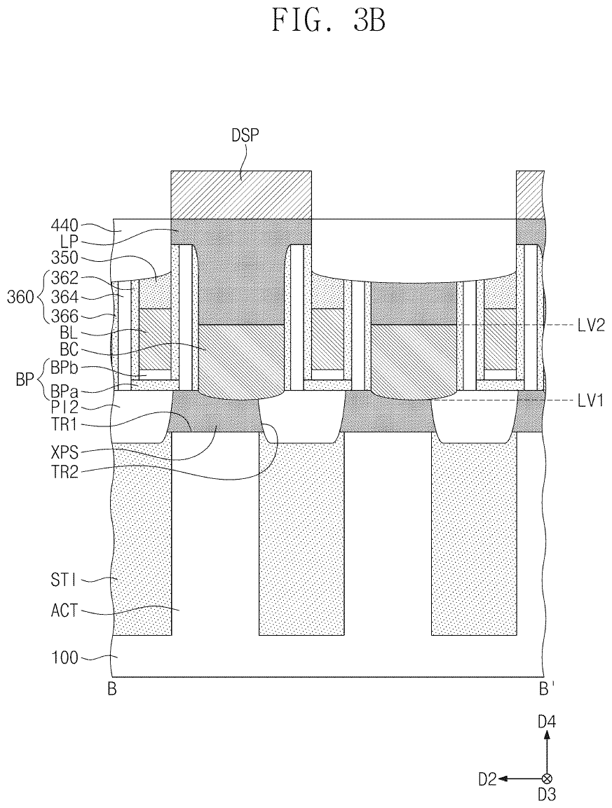

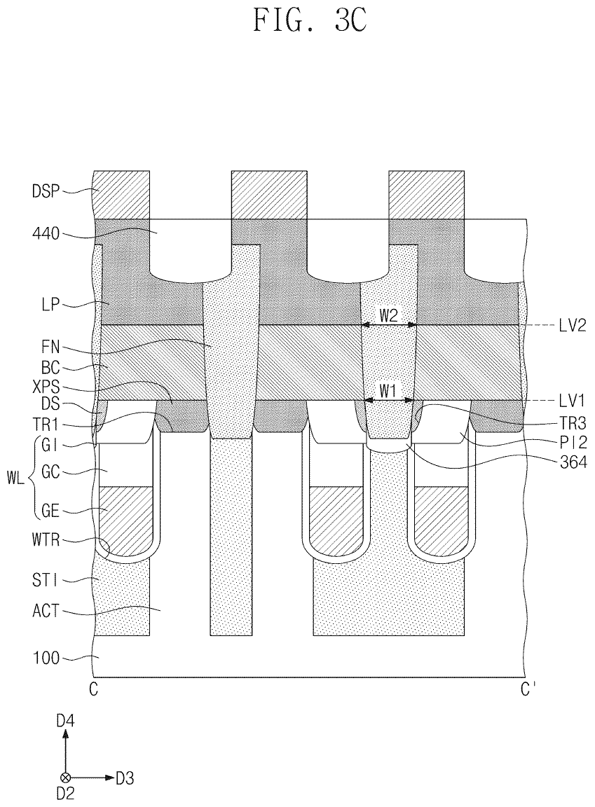

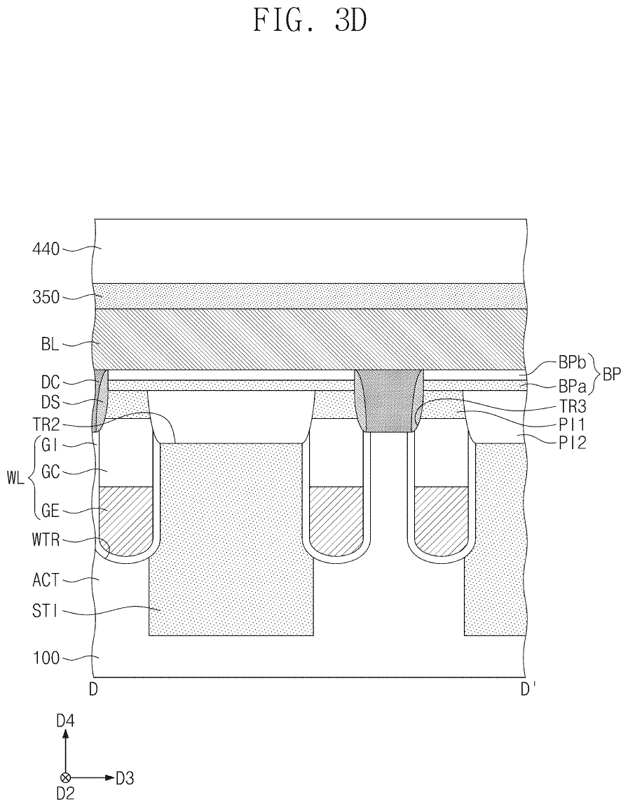

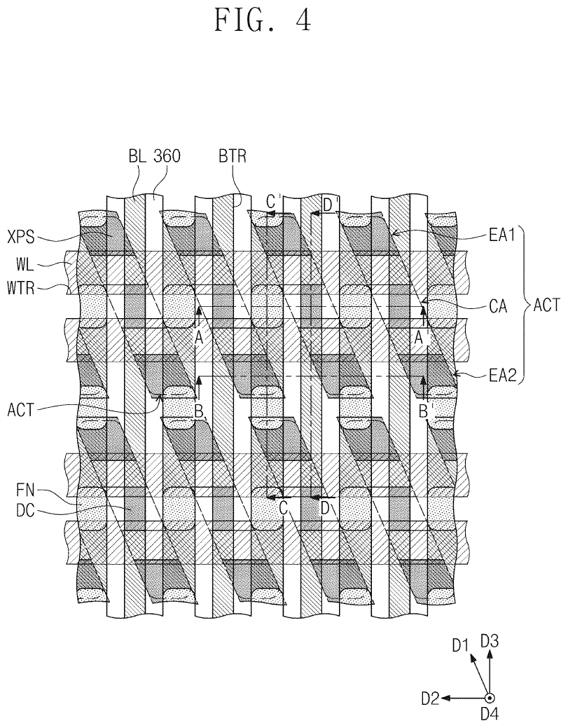

FIG. 1 is a plan view illustrating a semiconductor device according to some example embodiments of the inventive concepts. FIG. 2 is an enlarged view of some components of FIG. 1. FIGS. 3A, 3B, 3C and 3D are cross-sectional views corresponding to lines A-A′, B-B′, C-C′ and D-D′ of FIG. 1, respectively. FIG. 4 is a plan view illustrating components provided below a second level of FIG. 3C in the semiconductor device of FIG. 1.

Referring to FIGS. 1 to 3D, a substrate 100 may be provided. The substrate 100 may be a semiconductor substrate such as a silicon substrate, a germanium substrate, or a silicon-germanium substrate.

A device isolation pattern STI may be disposed in the substrate 100 and may define an active pattern ACT. The active pattern ACT may be provided in plurality. For example, the active patterns ACT may include portions of the substrate 100, which are surrounded by the device isolation pattern STI. In the present specification, the substrate 100 may be defined as another portion of the substrate 100 except the portions of the substrate 100 unless otherwise stated, for the purpose of ease and convenience in explanation.

Each of the active patterns ACT may have a long shape extending in a first direction D1 parallel to a bottom surface of the substrate 100. The active patterns ACT may be spaced apart from each other in a second direction D2 and a third direction D3 which are parallel to the bottom surface of the substrate 100 and intersect each other. The first to third directions D1, D2 and D3 may intersect each other. The active patterns ACT may have a shape protruding in a fourth direction D4 perpendicular to the bottom surface of the substrate 100. For example, the active pattern ACT may include silicon (e.g., single-crystalline silicon).

The active pattern ACT may include a first edge portion EA1, a second edge portion EA2 spaced apart from the first edge portion EA1 in the first direction D1, and a center portion CA between the first edge portion EA1 and the second edge portion EA2. The first edge portion EA1 and the second edge portion EA2 may be both end portions of the active pattern ACT in the first direction D1. The center portion CA may be disposed between a pair of word lines WL (to be described later) intersecting the active pattern ACT. The center portions CA of the active patterns ACT may be spaced apart from each other in the second and third directions D2 and D3. Dopants (e.g., n-type or p-type dopants) may be provided in the first and second edge portions EA1 and EA2 and the center portion CA.

The active patterns ACT adjacent to each other may be arranged in a line in the first direction D1 (or an opposite direction thereto), the second direction D2 (or an opposite direction thereto) or the third direction D3 (or an opposite direction thereto). In the present specification, it may be understood that when the active patterns ACT are arranged in a line in a direction, the center portions CA of the adjacent active patterns ACT may be arranged in the direction. In some example embodiments, as shown in FIG. 2, a first active pattern ACT1, a second active pattern ACT2, a third active pattern ACT3 and a fourth active pattern ACT4 may be arranged in a clockwise direction. The first active pattern ACT1 and the second active pattern ACT2 adjacent thereto may be arranged in a line in the second direction D2. The first active pattern ACT1 and the third active pattern ACT3 adjacent thereto may be arranged in a line in the first direction D1. The first active pattern ACT1 and the fourth active pattern ACT4 adjacent thereto may be arranged in a line in the third direction D3.

The first edge portion EA1 of the first active pattern ACT1 and the first edge portion EA1 of the second active pattern ACT2 may be adjacent to each other in the second direction D2. The first edge portion EA1 of the first active pattern ACT1 and the second edge portion EA2 of the second active pattern ACT2 may be adjacent to each other in the third direction D3. The first edge portion EA1 of the first active pattern ACT1 and the second edge portion EA2 of the third active pattern ACT3 may be adjacent to each other and may be spaced apart from each other in the first direction D1.

According to the inventive concepts, the active patterns ACT may be arranged in a line in the first direction D1 (or the opposite direction thereto), the second direction D2 (or the opposite direction thereto) or the third direction D3 (or the opposite direction thereto), and thus arrangement of components in the semiconductor device may be simplified. As a result, difficulty of a patterning process, etc. of manufacturing the semiconductor device may be reduced to more easily or simply manufacture the semiconductor device with greater accuracy and precision. In addition, the components may be relatively simply arranged to improve an integration density of the semiconductor device.

The device isolation pattern STI may include an insulating material (e.g., at least one of silicon oxide and silicon nitride). The device isolation pattern STI may be a single layer formed of a single material or a composite layer including two or more materials. In the present specification, the term ‘A or B’, ‘at least one of A and B’, ‘at least one of A or B’, A, B or C′, ‘at least one of A, B and C’, or ‘at least one of A, B, or C’ may include any and all combinations of one or more of the associated listed items.

A word line WL may intersect the active patterns ACT and the device isolation pattern STI. The word line WL may be provided in plurality. The word lines WL may extend in the second direction D2 and may be spaced apart from each other in the third direction D3. A pair of the word lines WL spaced apart from each other in the third direction D3 may intersect the active patterns ACT adjacent to each other in the second direction D2. For example, as shown in FIG. 2, a first word line WL1 and a second word line WL2 may be spaced apart from each other in the third direction D3 and may intersect the first and second active patterns ACT1 and ACT2 adjacent to each other in the second direction D2.

Each of the word lines WL may include a gate electrode GE, a gate dielectric pattern GI, and a gate capping pattern GC. The gate electrode GE may penetrate the active patterns ACT and the device isolation pattern STI in the second direction D2. The gate dielectric pattern GI may be disposed between the gate electrode GE and the active patterns ACT and between the gate electrode GE and the device isolation pattern STI. The gate capping pattern GC may be disposed on the gate electrode GE to cover a top surface of the gate electrode GE. For example, the gate electrode GE may include a conductive material. For example, the gate dielectric pattern GI may include at least one of silicon oxide and a high-k dielectric material. In the present specification, the high-k dielectric material may be defined as a material having a dielectric constant higher than that of silicon oxide. For example, the gate capping pattern GC may include silicon nitride.

Storage node pads XPS may be provided on the first and second edge portions EA1 and EA2 of the active patterns ACT. The storage node pads XPS may be spaced apart from each other in the first direction D1 and the second direction D2. The storage node pads XPS may be electrically connected to the first and second edge portions EA1 and EA2.

In some example embodiments, as shown in FIG. 2, each of the storage node pads XPS may be electrically connected to a corresponding one of the first and second edge portions EA1 and EA2. For example, a first storage node pad XPS1 may be connected to the first edge portion EA1 of the first active pattern ACT1. For example, a second storage node pad XPS2 may be connected to the second edge portion EA2 of the second active pattern ACT2. For example, a third storage node pad XPS3 may be connected to the second edge portion EA2 of the third active pattern ACT3. For example, a fourth storage node pad XPS4 may be connected to the first edge portion EA1 of the fourth active pattern ACT4.

For example, the storage node pad XPS may have a parallelogram shape when viewed in a plan view. For example, the storage node pad XPS may have two sides which extend in the first direction D1 and are opposite to each other, and other two sides which extend in the second direction D2 and are opposite to each other. However, example embodiments of the inventive concepts are not limited thereto.

A width of the storage node pad XPS may be changed depending on a direction and a level (a level may refer to a height or position along the vertical, fourth direction D4). For example, a width of the storage node pad XPS in the third direction D3 may decrease as a level decreases. In some example embodiments, a width of the storage node pad XPS in the second direction D2 may increase as a level decreases. However, example embodiments of the inventive concepts are not limited thereto.

The storage node pad XPS may include the same or substantially the same material as a storage node contact BC to be described later. For example, the storage node pad XPS may include silicon (for example, a dopant-doped poly-silicon or the like). In some example embodiments, the storage node pad XPS may further include a metal material. For example, the storage node pad XPS may be a single layer formed of a single material or a composite layer including two or more materials.

A bit line node contact DC may be provided on each of the active patterns ACT, and in other words, the bit line node contact DC may be provided in plurality. The bit line node contacts DC may be electrically connected to the center portions CA of the active patterns ACT, respectively. The bit line node contacts DC may be spaced apart from each other in the second and third directions D2 and D3. The bit line node contacts DC may be disposed between the active patterns ACT and bit lines BL to be described later, respectively. In some example embodiments, a lower portion of the bit line node contact DC may be buried in the center portion CA of the active pattern ACT. Each of the bit line node contacts DC may electrically connect a corresponding one of the bit lines BL to the center portion CA of a corresponding one of the active patterns ACT. For example, the bit line node contact DC may include silicon (for example, a dopant-doped poly-silicon or the like), but embodiments of the inventive concepts are not limited thereto. In some example embodiments, the bit line node contact DC may further include at least one of metal materials (e.g., Ti, Mo, W, Cu, Al, Ta, Ru, Ir, etc. and alloys/compounds thereof).

In some example embodiments, a first pad insulating pattern PI1 and a second pad insulating pattern PI2 may surround side surfaces of the storage node pads XPS and side surfaces of the bit line node contacts DC. The first pad insulating pattern PI1 and the second pad insulating pattern PI2 may electrically insulate the storage node pads XPS and the bit line node contacts DC from each other. For example, each of the first pad insulating pattern PI1 and the second pad insulating pattern PI2 may include an insulating material.

A bit line node contact spacer DS may be provided on the side surface of the bit line node contact DC. For example, a pair of the bit line node contact spacers DS may cover both side surfaces of the bit line node contact DC, which face the third direction D3 and the opposite direction thereto, respectively. For example, the bit line node contact spacer DS may be disposed between the bit line node contact DC and the first pad insulating pattern PI1 adjacent thereto in the third direction D3. For example, the bit line node contact spacer DS may be provided on the side surface of one bit line node contact DC and may extend onto the side surface of another bit line node contact DC adjacent to the one bit line node contact DC in the second direction D2. The second pad insulating pattern PI2 may be disposed between the one bit line node contact DC and the adjacent bit line node contact DC, and the bit line node contact spacer DS may extend onto a side surface of the second pad insulating pattern PI2.

A bit line BL may be provided on the bit line node contact DC. The bit line BL may extend in the third direction D3. The bit line BL may be provided in plurality. The bit lines BL may be spaced apart from each other in the second direction D2. The bit line BL may include a metal material. For example, the bit line BL may include a metal material (e.g., Ti, Mo, W, Cu, Al, Ta, Ru, Ir, etc. and alloys/compounds thereof). In some example embodiments, the bit line BL may further include a metal silicide or a metal nitride.

The bit line BL may be disposed on the center portions CA of the active patterns ACT arranged in a line in the third direction D3 and may be electrically connected to the active patterns ACT arranged in a line through the bit line node contacts DC. For example, as shown in FIG. 2, a first bit line BL1 may be disposed on the center portions CA of the first active pattern ACT1 and the fourth active pattern ACT4 arranged in a line in the third direction D3 and may be electrically connected to the center portions CA of the first and fourth active patterns ACT1 and ACT4. For example, a second bit line BL2 may be disposed on the center portions CA of the second active pattern ACT2 and the third active pattern ACT3 arranged in a line in the third direction D3 and may be electrically connected to the center portions CA of the second and third active patterns ACT2 and ACT3.

A buffer pattern BP may be disposed under the bit line BL and may cover the substrate 100. For example, the buffer pattern BP may be disposed between the bit line BL and the first pad insulating pattern PI1 and between the bit line BL and the second pad insulating pattern PI2. For example, the buffer pattern BP may be disposed between the bit line node contacts DC adjacent to each other in the third direction D3. For example, the buffer pattern BP may include at least one of silicon oxide, silicon nitride, silicon oxynitride, or a high-k dielectric material. The buffer pattern BP may be a single layer formed of a single material or a composite layer including two or more materials. For example, the buffer pattern BP may be a composite layer including a lower buffer pattern BPa and an upper buffer pattern BPb.

A bit line capping pattern 350 may be provided on a top surface of the bit line BL. The bit line capping pattern 350 may extend in the third direction D3 together with the bit line BL. The bit line capping pattern 350 may be provided in plurality. The plurality of bit line capping patterns 350 may be spaced apart from each other in the second direction D2. The bit line capping pattern 350 may vertically overlap (for example, overlap in the fourth direction D4) with the bit line BL. The bit line capping pattern 350 may be formed of a single layer or a plurality of layers. For example, the bit line capping pattern 350 may include a first capping pattern, a second capping pattern and a third capping pattern, which are sequentially stacked. Each of the first to third capping patterns may include silicon nitride. Alternatively, the bit line capping pattern 350 may include four or more stacked capping patterns.

A bit line spacer 360 may be provided on a side surface of the bit line BL and a side surface of the bit line capping pattern 350. The bit line spacer 360 may cover the side surface of the bit line BL and the side surface of the bit line capping pattern 350. The bit line spacer 360 may extend in the third direction D3 on the side surface of the bit line BL.

The bit line spacer 360 may include a plurality of spacers. For example, the bit line spacer 360 may include a first spacer 362, a second spacer 364, and a third spacer 366. The third spacer 366 may be provided on the side surface of the bit line BL and the side surface of the bit line capping pattern 350. The first spacer 362 may be disposed between the bit line BL and the third spacer 366 and between the bit line capping pattern 350 and the third spacer 366. The second spacer 364 may be disposed between the first spacer 362 and the third spacer 366. For example, the second spacers 364 on the bit lines BL adjacent to each other may be connected to each other, but embodiments of the inventive concepts are not limited thereto.

For example, the first to third spacers 362, 364 and 366 may each independently include at least one of silicon oxide, silicon nitride, silicon oxycarbide, and silicon oxy-carbonitride. Alternatively, the second spacer 364 may include an air gap separating the first and third spacers 362 and 366 from each other.

A storage node contact BC may be provided between the bit lines BL adjacent to each other. For example, the storage node contact BC may be disposed between the bit line spacers 360 adjacent to each other. The storage node contact BC may be provided in plurality. The plurality of storage node contacts BC may be spaced apart from each other in the second and third directions D2 and D3. The storage node contacts BC adjacent to each other may be arranged in the second or third directions D2 or D3. The storage node contacts BC may be provided on the storage node pads XPS. The storage node contacts BC may be electrically connected to the first and second edge portions EA1 and EA2 through the storage node pads XPS.

For example, as shown in FIG. 2, each of the storage node contacts BC may be electrically connected to a corresponding one of the first and second edge portions EA1 and EA2 through a corresponding one of the storage node pads XPS. For example, a first storage node contact BC1 may be electrically connected to the first edge portion EA1 of the first active pattern ACT1 through the first storage node pad XPS1. For example, a second storage node contact BC2 may be electrically connected to the second edge portion EA2 of the second active pattern ACT2 through the second storage node pad XPS2. For example, a third storage node contact BC3 may be electrically connected to the second edge portion EA2 of the third active pattern ACT3 through the third storage node pad XPS3. For example, a fourth storage node contact BC4 may be electrically connected to the first edge portion EA1 of the fourth active pattern ACT4 through the fourth storage node pad XPS4.

The first to fourth storage node contacts BC1, BC2, BC3 and BC4 may be disposed between the first bit line BL1 and the second bit line BL2. The first to fourth storage node contacts BC1, BC2, BC3 and BC4 may be arranged in a line in the third direction D3. For example, the second storage node contact BC2, the first storage node contact BC1, the third storage node contact BC3 and the fourth storage node contact BC4 may be arranged in a line in the third direction D3 and may be sequentially arranged in the third direction D3.

A width of the storage node contact BC may be changed depending on a level. For example, a width of the storage node contact BC in the third direction D3 may increase as a level decreases, but embodiments of the inventive concepts are not limited thereto. For example, the storage node contact BC may include silicon (for example, a dopant-doped poly-silicon or the like).

Since the storage node pad XPS is provided, the storage node contact BC may be electrically connected to a corresponding one of the first and second edge portions EA1 and EA2, and the electrical connection may be more easily or simply produced during manufacturing. For example, even though the storage node contact BC is misaligned and thus does not vertically overlap (for example, overlap in the fourth direction D4) with the corresponding edge portion, the storage node contact BC may be electrically connected to the corresponding edge portion through the storage node pad XPS. If the storage node contact BC is in direct contact with the corresponding edge portion, a contact resistance therebetween may be increased by misalignment. However, the storage node pad XPS may prevent or reduce an increase in contact resistance between the storage node contact BC and the corresponding edge portion.

A fence pattern FN may be provided between the bit lines BL adjacent to each other and between the storage node contacts BC adjacent to each other in the third direction D3. The fence pattern FN may separate the storage node contacts BC adjacent in the third direction D3 from each other and may be in contact with the adjacent storage node contacts BC. The fence pattern FN may be provided in plurality, and the plurality of fence patterns FN may be spaced apart from each other in the third direction D3. For example, each of the fence patterns FN may include lower portions which are arranged in a line in the second direction D2 and are alternately arranged with the bit lines BL, and an upper portion of the fence pattern FN may be disposed on the bit lines BL to connect the lower portions. For example, a filling pattern 440 to be described later may penetrate the upper portion of the fence pattern FN in the fourth direction D4. For example, the fence pattern FN may include at least one of silicon oxide, silicon nitride, silicon oxycarbide, and silicon oxy-carbonitride.

A width of the fence pattern FN may be changed depending on a level. For example, a width of the fence pattern FN in the third direction D3 may decrease as a level decreases. For example, the fence pattern FN may have a first width W1 at a first level LV1 and may have a second width W2, greater than the first width W1, at a second level LV2 higher than the first level LV1. Here, the first level LV1 may be defined as a level at which a bottom surface of the storage node contact BC is located, and the second level LV2 may be defined as a level at which a top surface of the storage node contact BC is located. This may be because the storage node contact BC is formed prior to the fence pattern FN in a manufacturing method to be described later.

Referring to FIG. 4, for example, the fence pattern FN may have a rounded corner under the second level LV2 when viewed in a plan view. For example, the lower portion of the fence pattern FN may have a rounded corner between the bit lines BL. The storage node contact BC adjacent to the fence pattern FN in the third direction D3 may include a protrusion protruding toward the fence pattern FN. The protrusion of the storage node contact BC may protrude between the bit line BL and the fence pattern FN. For example, the protrusion of the storage node contact BC may be provided at each corner, and thus the storage node contact BC may have four protrusions. The planar features of the fence pattern FN and the storage node contact BC in FIG. 4 may also be because the storage node contact BC is formed prior to the fence pattern FN in the manufacturing method to be described later. However, the planar shape of FIG. 4 is illustrated as an example, and embodiments of the inventive concepts are not limited thereto.

Referring again to FIGS. 1 to 3D, a landing pad LP may be provided on the storage node contact BC. The landing pad LP may be provided in plurality. The plurality of landing pads LP may be spaced apart from each other in the second and third directions D2 and D3. Each of the landing pads LP may be electrically connected to a corresponding one of the first and second edge portions EA1 and EA2 through a corresponding one of the storage node contacts BC and a corresponding one of the storage node pads XPS.

The landing pad LP may include a lower portion and an upper portion. The lower portion of the landing pad LP may vertically overlap (for example, overlap in the fourth direction D4) with the storage node contact BC. The upper portion of the landing pad LP may be shifted from the lower portion in the third direction D3 (or the opposite direction thereto). For example, the lower portion and the upper portion of the landing pad LP may include the same or substantially the same material. Alternatively, the lower portion and the upper portion of the landing pad LP may include different materials. The landing pad LP may include a metal material (e.g., Ti, Mo, W, Cu, Al, Ta, Ru, Ir, etc. and alloys/compounds thereof).

A filling pattern 440 may surround the landing pad LP when viewed in a plan view. The filling pattern 440 may be disposed between the landing pads LP adjacent to each other. The filling pattern 440 may have a mesh shape including holes penetrated by the landing pads LP, when viewed in a plan view. For example, the filling pattern 440 may include at least one of silicon nitride, silicon oxide, silicon oxynitride, or any combination thereof. Alternatively, the filling pattern 440 may include an empty space (for example, an air gap) including air.

A data storage pattern DSP may be provided on the landing pad LP. The data storage pattern DSP may be provided in plurality. The plurality of data storage patterns DSP may be spaced apart from each other in the second and third directions D2 and D3. Each of the data storage patterns DSP may be electrically connected to a corresponding one of the first and second edge portions EA1 and EA2 through a corresponding one of the landing pads LP, a corresponding one of the storage node contacts BC and a corresponding one of the storage node pads XPS.

For some examples, the data storage pattern DSP may be a capacitor including a lower electrode, a dielectric layer and an upper electrode. In this case, the semiconductor device according to the inventive concepts may be a dynamic random access memory (DRAM) device. In some example embodiments, the data storage pattern DSP may include a magnetic tunnel junction pattern. In this case, the semiconductor device according to the inventive concepts may be a magnetic random access memory (MRAM) device. In some example embodiments, the data storage pattern DSP may include a phase-change material or a variable resistance material. In this case, the semiconductor device according to the inventive concepts may be a phase-change random access memory (PRAM) device or a resistive random access memory (ReRAM) device. However, example embodiments of the inventive concepts are not limited thereto, and in some example embodiments, the data storage pattern DSP may include at least one of other various structures and/or materials capable of storing data.

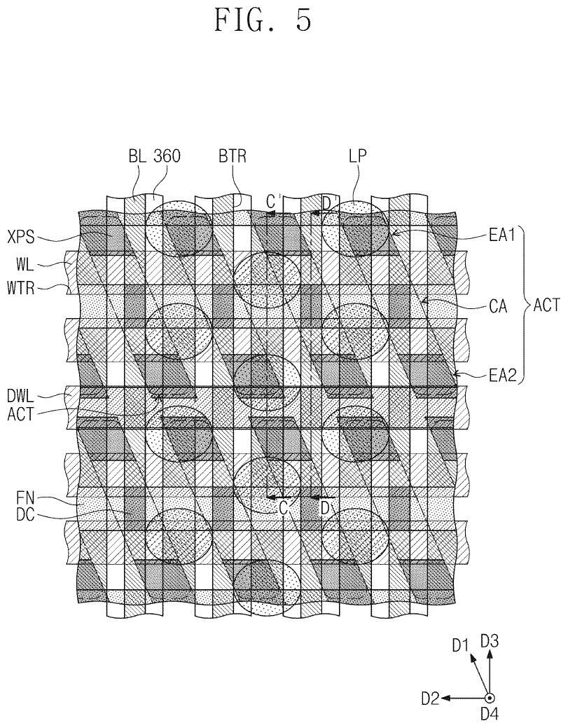

Hereinafter, some example embodiments of the inventive concepts will be described with reference to FIGS. 5 to 13D. In the following example embodiments, the descriptions to the same features as mentioned above will be omitted and differences between the following example embodiments and the above example embodiments will be mainly described, for the purpose of ease and convenience in explanation.

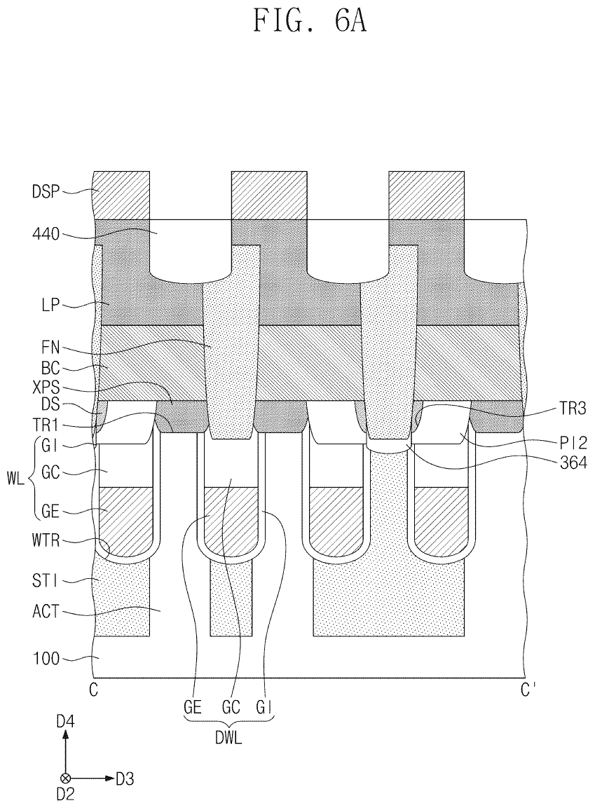

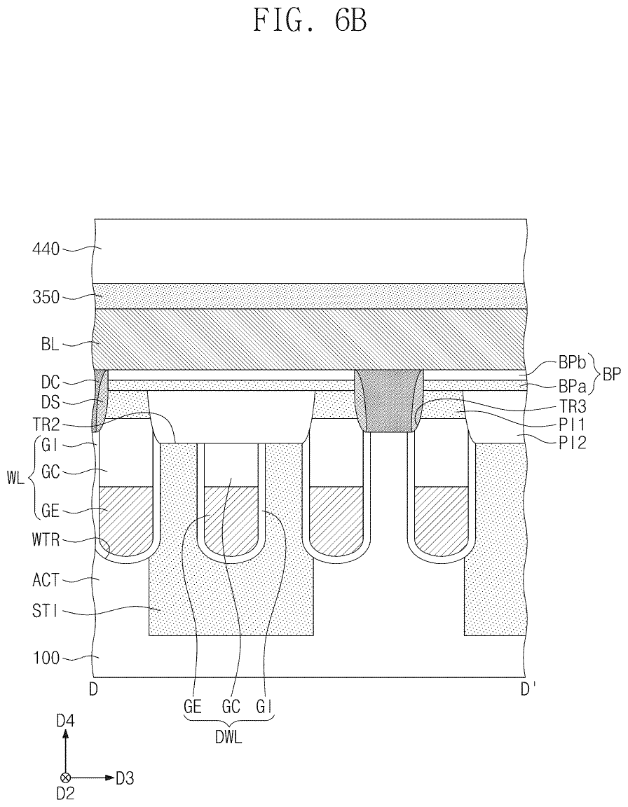

FIG. 5 is a plan view illustrating a semiconductor device according to some example embodiments of the inventive concepts. FIGS. 6A and 6B are cross-sectional views corresponding to lines C-C′ and D-D′ of FIG. 5, respectively.

Referring to FIGS. 5 to 6B, a dummy word line DWL may be provided. The dummy word line DWL may extend in the second direction D2 and may be spaced apart from the word lines WL in the third direction D3. The dummy word line DWL may be disposed between the active patterns ACT adjacent to each other in the third direction D3. For example, a portion of the device isolation pattern STI may be disposed between the active patterns ACT adjacent to each other in the third direction D3, and the dummy word line DWL may intersect the adjacent active patterns ACT and the portion of the device isolation pattern STI. The dummy word line DWL may include a gate electrode GE, a gate dielectric pattern GI, and a gate capping pattern GC.

For example, distances between the word lines WL arranged in the third direction D3 may not be constant. The dummy word line DWL may be disposed between the word lines WL spaced apart from each other by a relatively great distance. Thus, a loading effect according to a patterning density may be prevented or reduced in a patterning process for forming the word lines WL. As a result, the word lines WL may be formed, for example, more easily or simply formed.

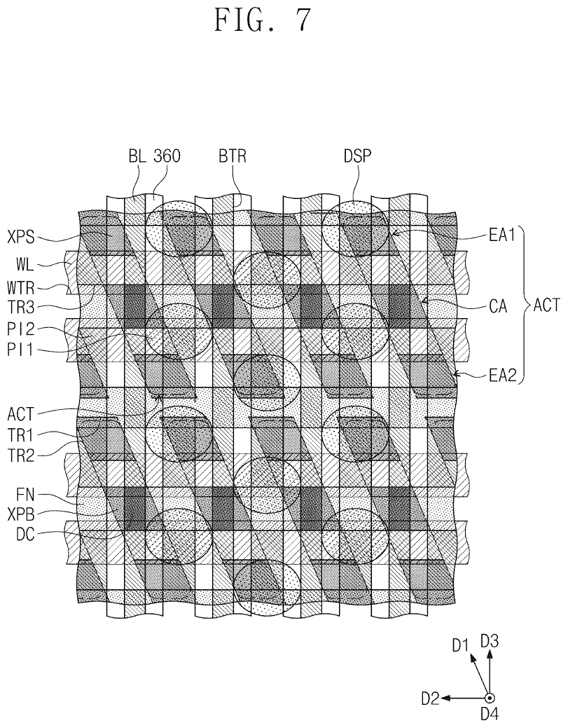

FIG. 7 is a plan view illustrating a semiconductor device according to some example embodiments of the inventive concepts.

Referring to FIG. 7, a bit line node pad XPB may be provided on the center portion CA of the active pattern ACT. The bit line node pad XPB may be electrically connected to the center portion CA of the active pattern ACT. The bit line BL may be electrically connected to the center portion CA of the active pattern ACT through the bit line node contact DC and the bit line node pad XPB. The bit line node pad XPB may be provided in plurality, and the plurality of bit line node pads XPB may be spaced apart from each other in the second and third directions D2 and D3. Each of the bit line node contacts DC may be electrically connected to the center portion CA of a corresponding one of the active patterns ACT through a corresponding one of the bit line node pads XPB.

The bit line node pads XPB and the storage node pads XPS may be alternately arranged in the first direction D1 when viewed in a plan view. More particularly, one bit line node pad XPB and two storage node pads XPS may be repeatedly and alternately arranged in the first direction D1.

The bit line node pad XPB may include the same or substantially the same material as the storage node contact BC. The bit line node pad XPB may include the same or substantially the same material as the storage node pad XPS. For example, the bit line node pad XPB may include silicon (for example, a dopant-doped poly-silicon or the like). In some example embodiments, the bit line node pad XPB may further include a metal material. For example, at least one of the bit line node pad XPB and the storage node pad XPS may further include a metal material. In some example embodiments, both the bit line node pad XPB and the storage node pad XPS may not include a metal material. For example, the bit line node pad XPB may be a single layer formed of a single material or a composite layer including two or more materials.

Since the bit line node pads XPB are provided, the bit line BL may be electrically connected to the center portion CA of the active pattern ACT, which may be achieved more easily or simply during manufacturing.

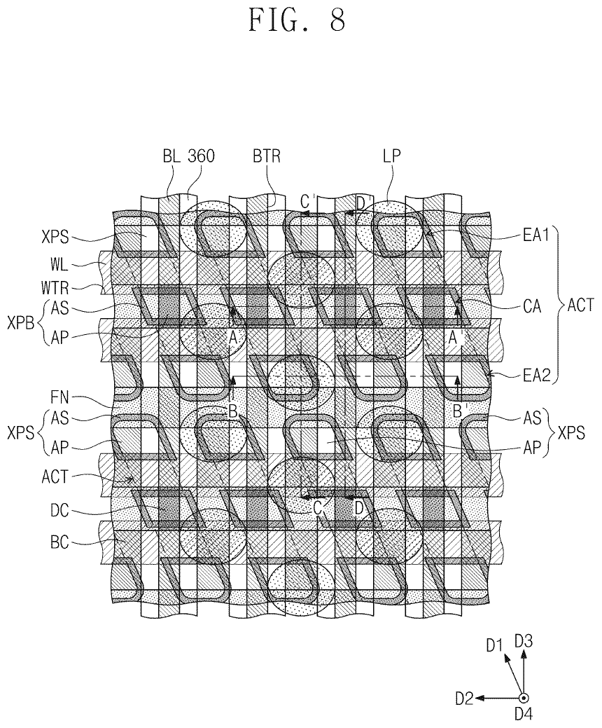

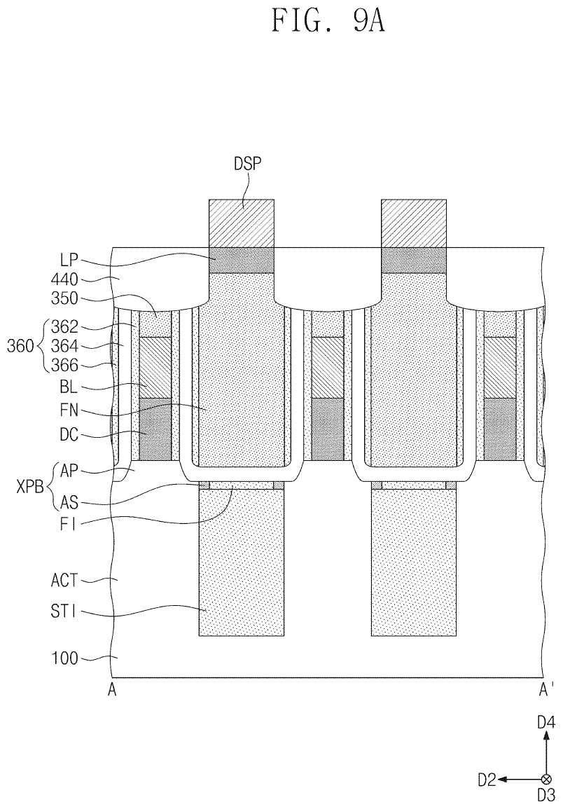

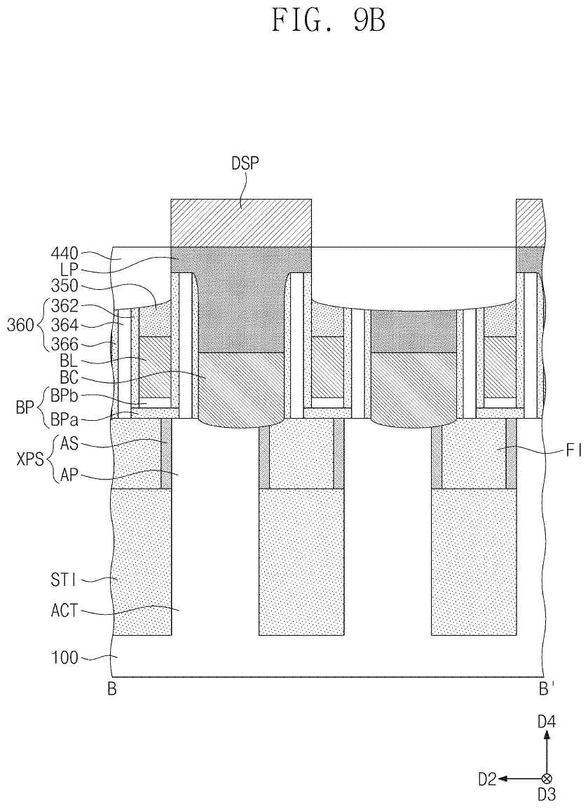

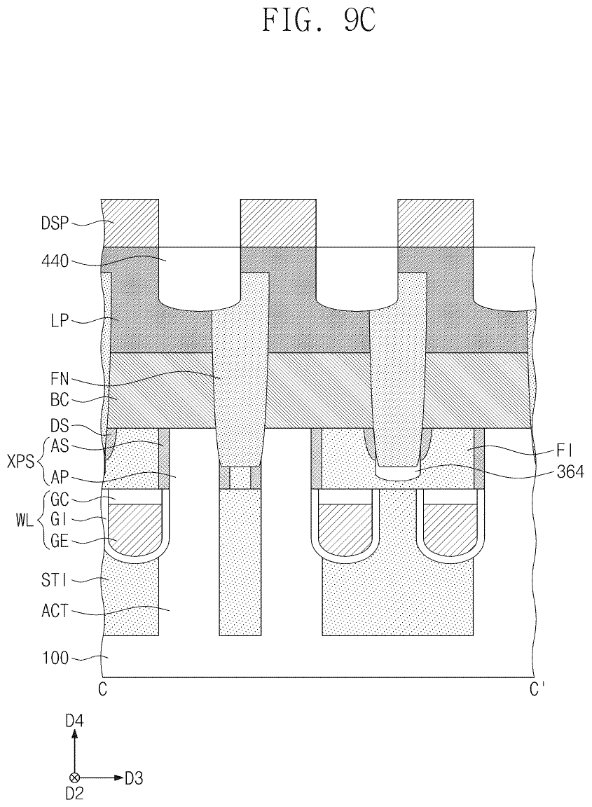

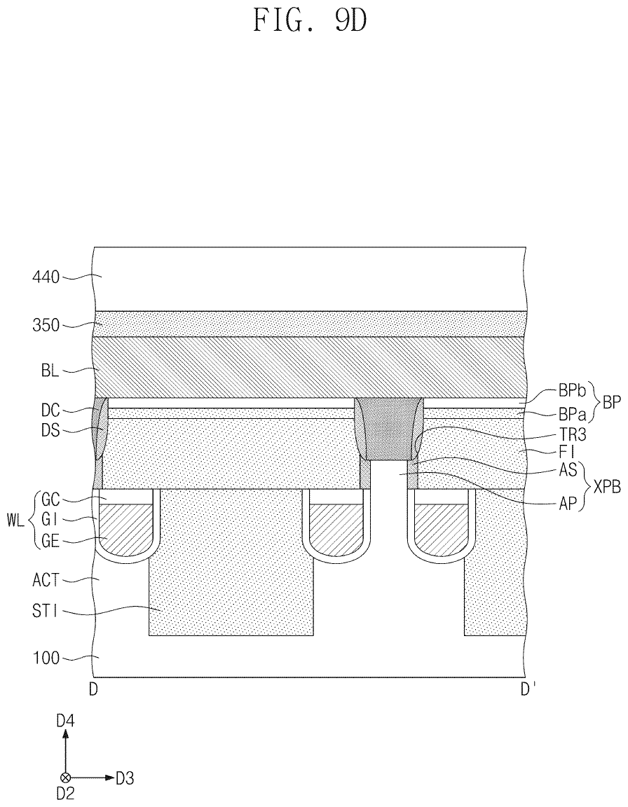

FIG. 8 is a plan view illustrating a semiconductor device according to some example embodiments of the inventive concepts. FIGS. 9A, 9B, 9C and 9D are cross-sectional views corresponding to lines A-A′, B-B′, C-C′ and D-D′ of FIG. 8, respectively.

Referring to FIGS. 8 to 9D, a storage node pad XPS may include an active pad AP and an active spacer AS. The active pad AP may include a portion of the active pattern ACT, which is surrounded by the active spacer AS. In some example embodiments, the active pattern ACT may be defined as another portion of the active pattern ACT except the portion of the active pattern ACT unless otherwise stated, for the purpose of ease and convenience in explanation. The active spacer AS may be disposed on the word line WL to cover a portion of the word line WL.

For example, the active pad AP may include silicon (e.g., single-crystalline silicon and the like). For example, the active spacer AS may include silicon (e.g., single-crystalline silicon, poly-silicon, etc.).

A bit line node pad XPB may further be provided and may include an active pad AP and an active spacer AS. Material features of the active pad AP and the active spacer AS of the bit line node pad XPB may be the same/similar as those of the storage node pad XPS.

A filling insulation pattern FI may be provided on the device isolation pattern STI. The filling insulation pattern FI may surround the storage node pad XPS and the bit line node pad XPB. The filling insulation pattern FI may cover top surfaces of the device isolation pattern STI and the word line WL. The filling insulation pattern FI may include an insulating material (e.g., at least one of silicon oxide and silicon nitride).

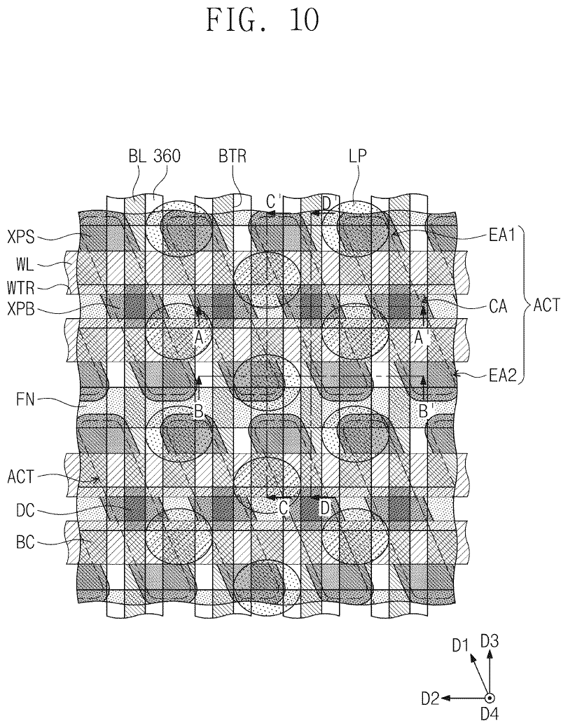

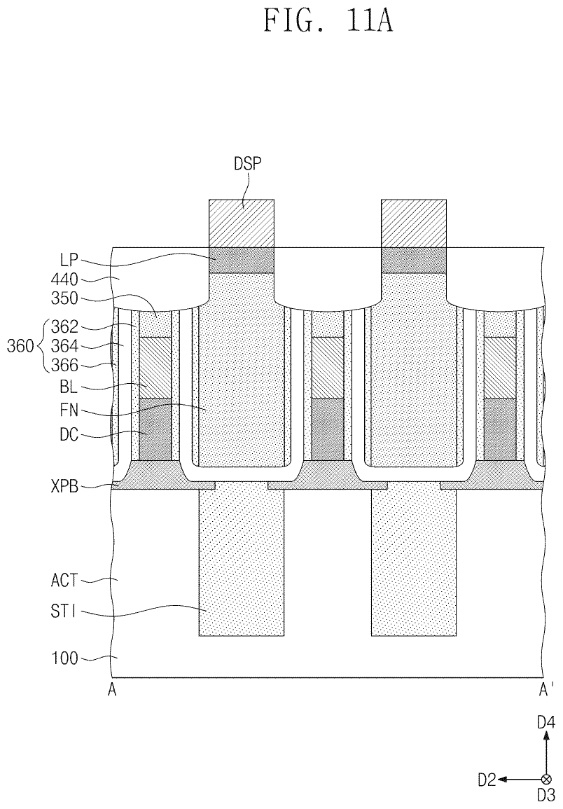

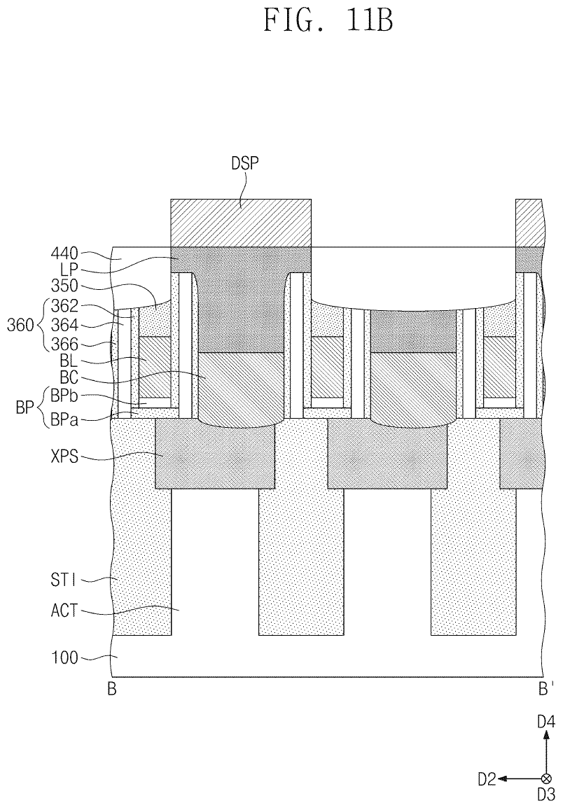

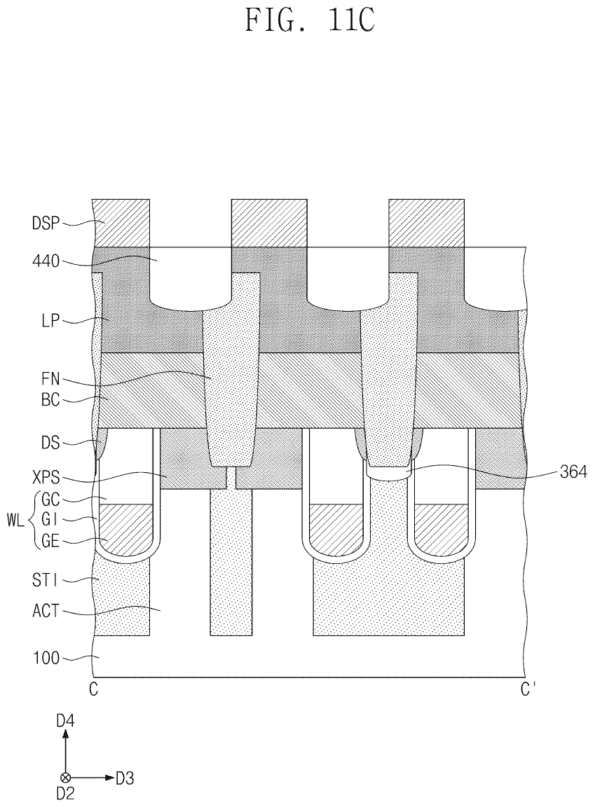

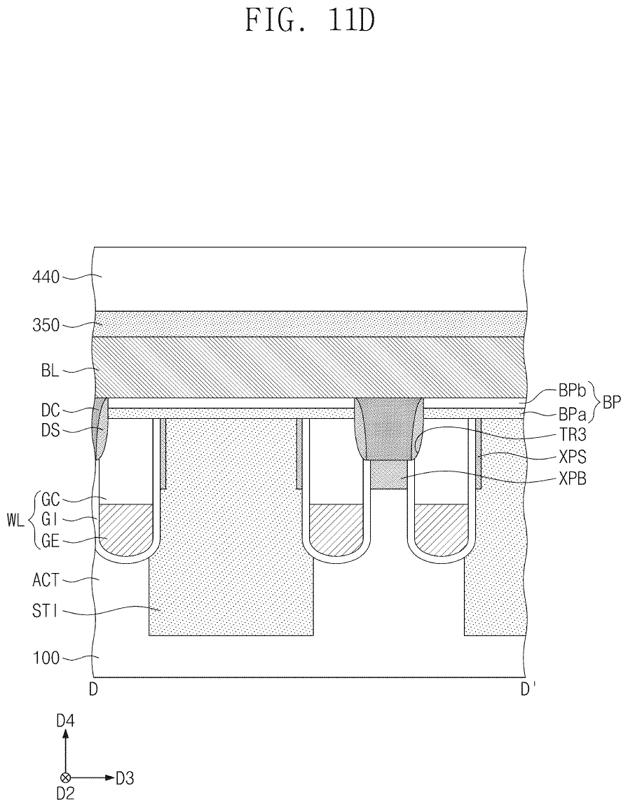

FIG. 10 is a plan view illustrating a semiconductor device according to some example embodiments of the inventive concepts. FIGS. 11A, 11B, 11C and 11D are cross-sectional views corresponding to lines A-A′, B-B′, C-C′ and D-D′ of FIG. 10, respectively.

Referring to FIGS. 10 to 11D, a storage node pad XPS and a bit line node pad XPB may be surrounded by the device isolation pattern STI. The storage node pad XPS and the bit line node pad XPB may penetrate the device isolation pattern STI in the fourth direction D4. The storage node pad XPS may cover a top surface of the first or second edge portion EA1 or EA2 of the active pattern ACT. The bit line node pad XPB may cover a top surface of the center portion CA of the active pattern ACT.

The word line WL may penetrate the storage node pad XPS and the bit line node pad XPB in the second direction D2. For example, the word line WL may not vertically overlap (for example, overlap in the fourth direction D4) with the storage node pad XPS and the bit line node pad XPB.

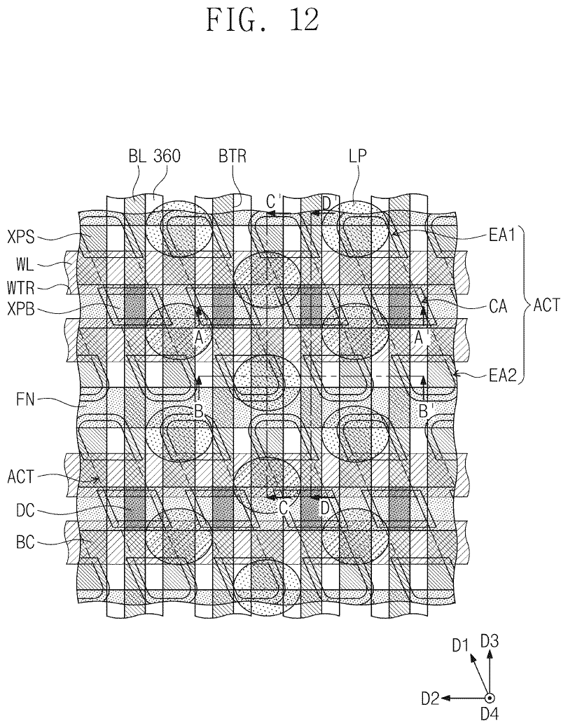

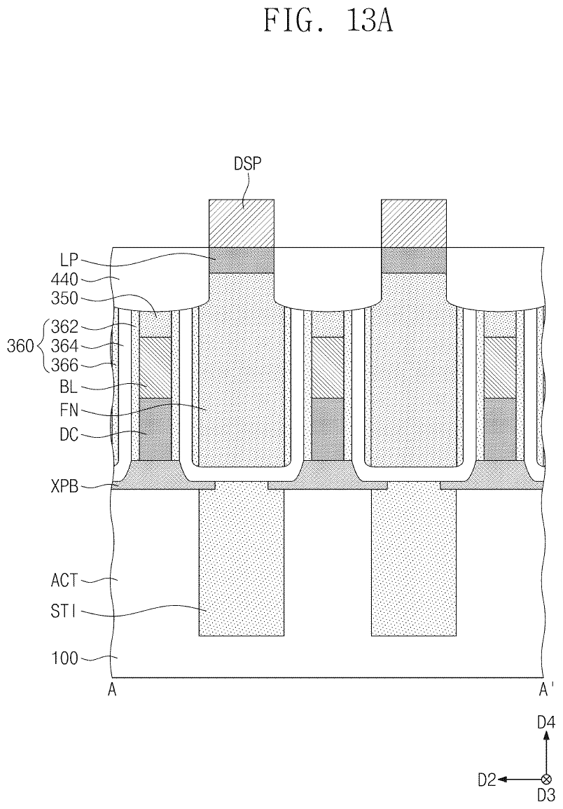

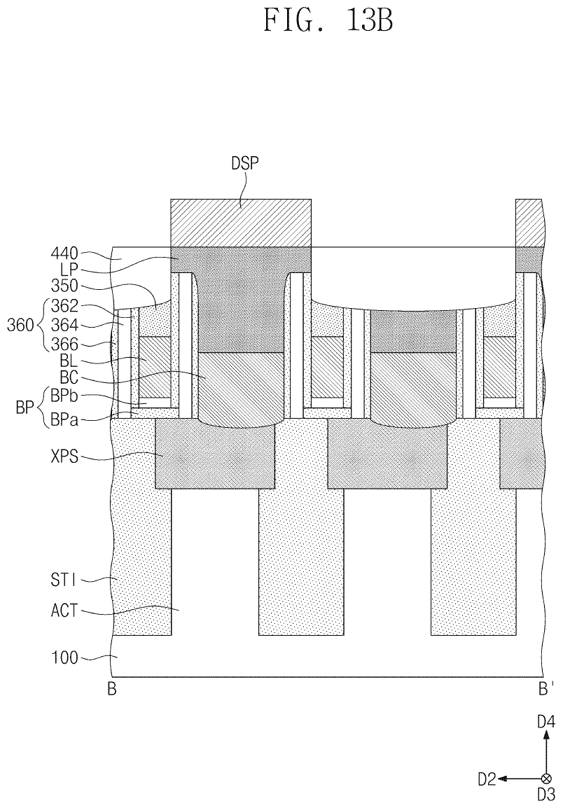

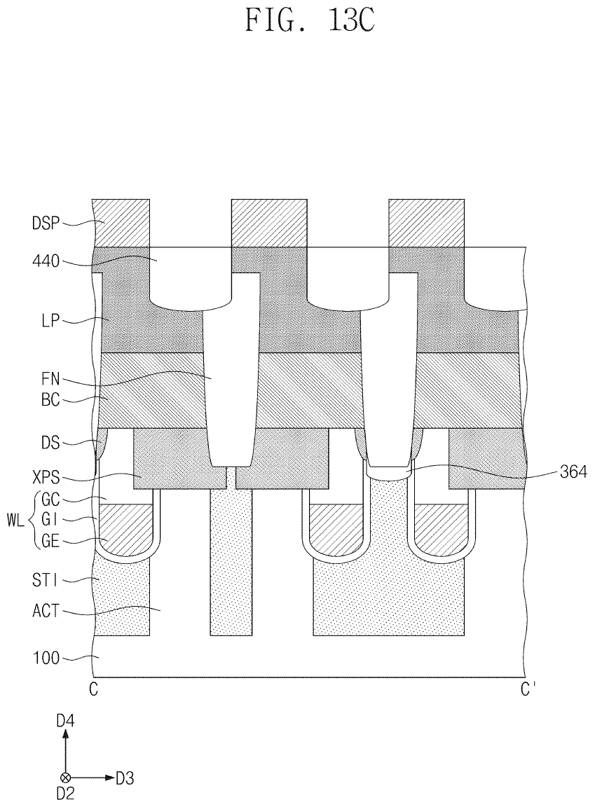

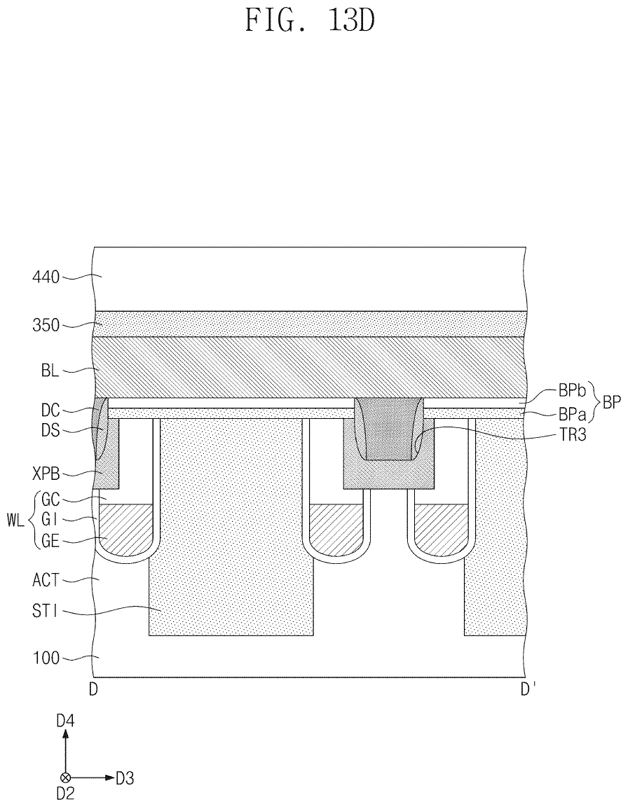

FIG. 12 is a plan view illustrating a semiconductor device according to some example embodiments of the inventive concepts. FIGS. 13A, 13B, 13C and 13D are cross-sectional views corresponding to lines A-A′, B-B′, C-C′ and D-D′ of FIG. 12, respectively.

Referring to FIGS. 12 to 13D, a storage node pad XPS and a bit line node pad XPB may be surrounded by the device isolation pattern STI. The storage node pad XPS and the bit line node pad XPB may penetrate the device isolation pattern STI in the fourth direction D4. The storage node pad XPS may cover the top surface of the first or second edge portion EA1 or EA2 of the active pattern ACT. The bit line node pad XPB may cover the top surface of the center portion CA of the active pattern ACT.

The storage node pad XPS and the bit line node pad XPB may be disposed on the word line WL to cover portions of the word line WL. The storage node pad XPS and the bit line node pad XPB may vertically overlap (for example, overlap in the fourth direction D4) with the portions of the word line WL.

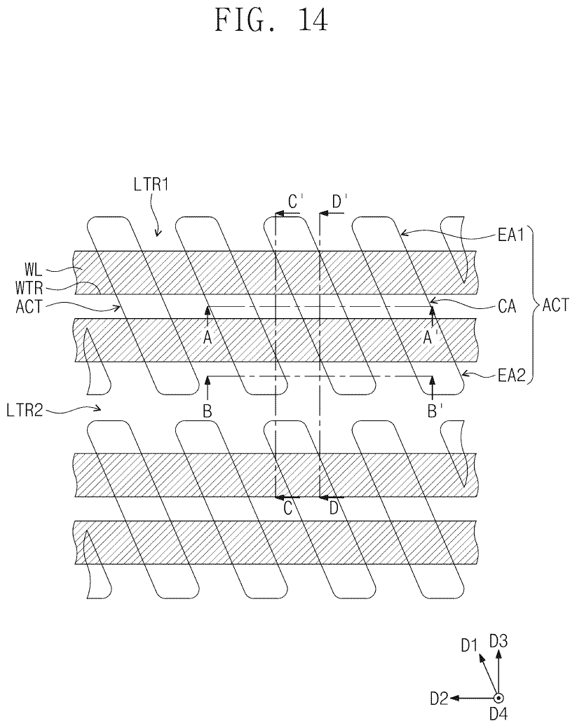

Hereinafter, methods of manufacturing semiconductor devices according to some example embodiments of the inventive concepts will be described with reference to FIGS. 14 to 36D. However, the descriptions to the same features as mentioned above will be omitted and differences from the aforementioned features will be mainly described, for the purpose of ease and convenience in explanation.

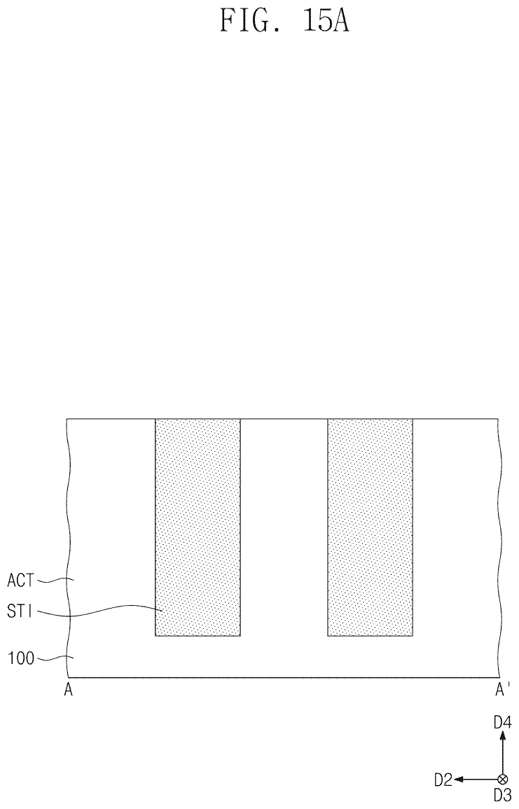

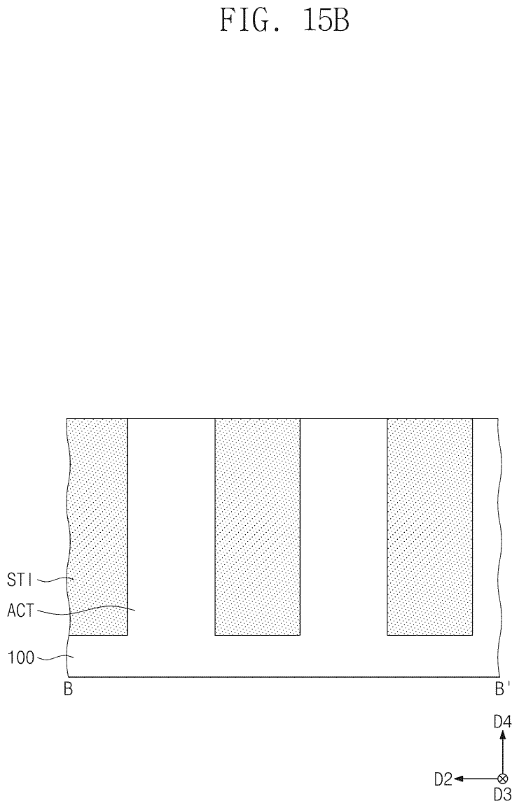

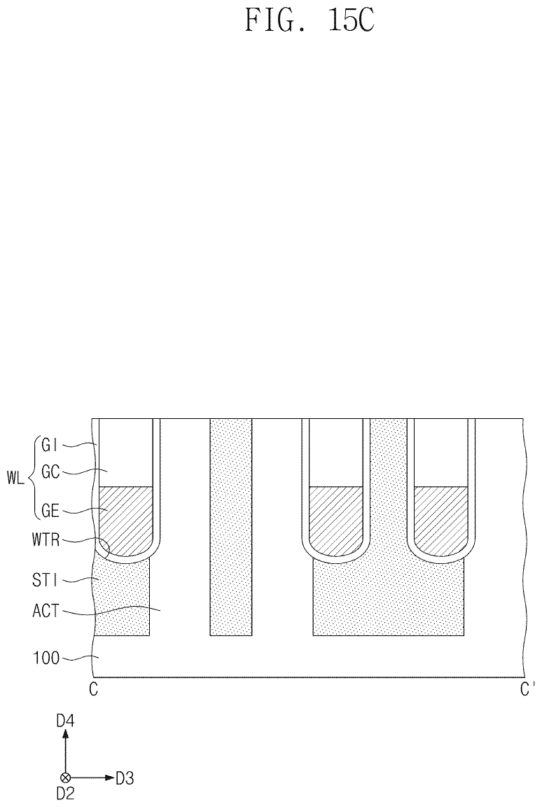

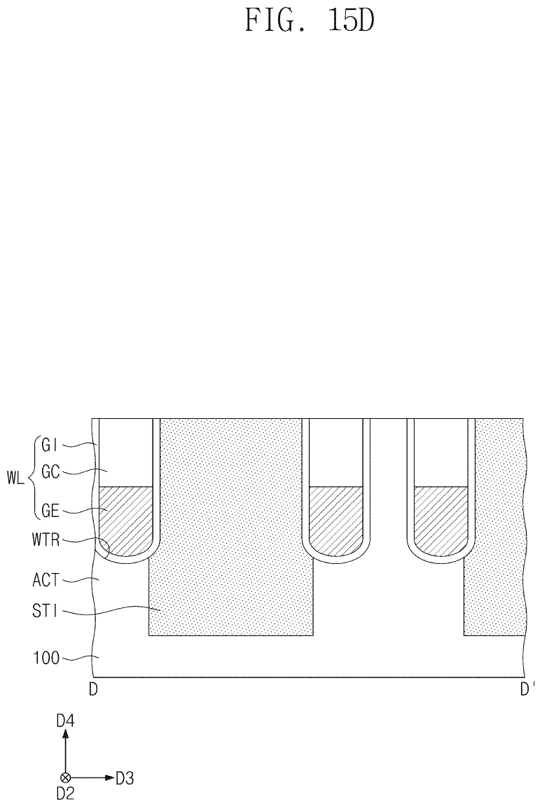

FIGS. 14 to 25D are views illustrating a method of manufacturing the semiconductor device of FIGS. 1 to 3D. More particularly, FIGS. 14, 16, 18, 20, 22 and 24 are plan views illustrating a method of manufacturing the semiconductor device of FIGS. 1 to 3D. FIGS. 15A, 17A, 19A, 21A, 23A and 25A are cross-sectional views corresponding to lines A-A′ of FIGS. 14, 16, 18, 20, 22 and 24, respectively. FIGS. 15B, 17B, 19B, 21B, 23B and 25B are cross-sectional views corresponding to lines B-B′ of FIGS. 14, 16, 18, 20, 22 and 24, respectively. FIGS. 15C, 17C, 19C, 21C, 23C and 25C are cross-sectional views corresponding to lines C-C′ of FIGS. 14, 16, 18, 20, 22 and 24, respectively. FIGS. 15D, 17D, 19D, 21D, 23D and 25D are cross-sectional views corresponding to lines D-D′ of FIGS. 14, 16, 18, 20, 22 and 24, respectively.

Referring to FIGS. 14 to 15D, a substrate 100 may be prepared. A removal process may be performed on the substrate 100, and thus active patterns ACT may be formed. A trench region may be formed between the active patterns ACT.

The removal process may include forming mask patterns on the substrate 100 by using an exposure process, and etching the substrate 100 using the mask patterns as etch masks. The exposure process and the etching process may be alternately repeated a plurality of times. For example, line patterns and first line trench regions LTR1, which extend in the first direction D1, may be formed using first exposure and etching processes.

Thereafter, second exposure and etching processes may be performed on the line patterns. By the second exposure and etching processes, second line trench regions LTR2 extending in the second direction D2 may be formed, and each of the line patterns may be divided into the active patterns ACT arranged in a line in the first direction D1.

A device isolation pattern STI may be formed to fill the first and second line trench regions LTR1 and LTR2. The formation of the device isolation pattern STI may include performing a physical vapor deposition (PVD) process, a chemical vapor deposition (CVD) process, or an atomic layer deposition (ALD) process.

Thereafter, a word line WL may be formed to intersect the active pattern ACT and the device isolation pattern STI. The formation of the word line WL may include forming a mask pattern on the active pattern ACT and the device isolation pattern STI, performing an anisotropic etching process using the mask pattern as an etch mask to form a word line trench region WTR, and filling the word line trench region WTR with the word line WL.

For example, the filling of the word line trench region WTR with the word line WL may include conformally depositing a gate dielectric pattern GI on an inner surface of the word line trench region WTR, filling the word line trench region WTR with a conductive layer, performing an etch-back process and/or a polishing process on the conductive layer to form a gate electrode GE, and forming a gate capping pattern GC filling a remaining portion of the word line trench region WTR on the gate electrode GE.

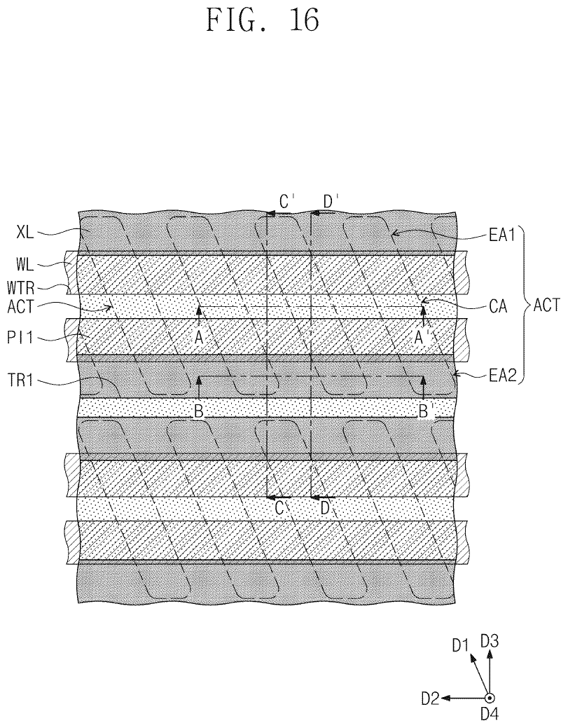

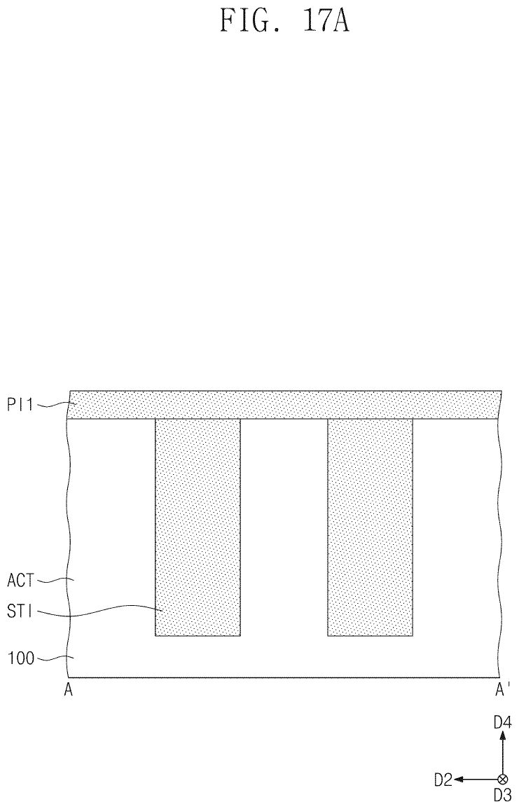

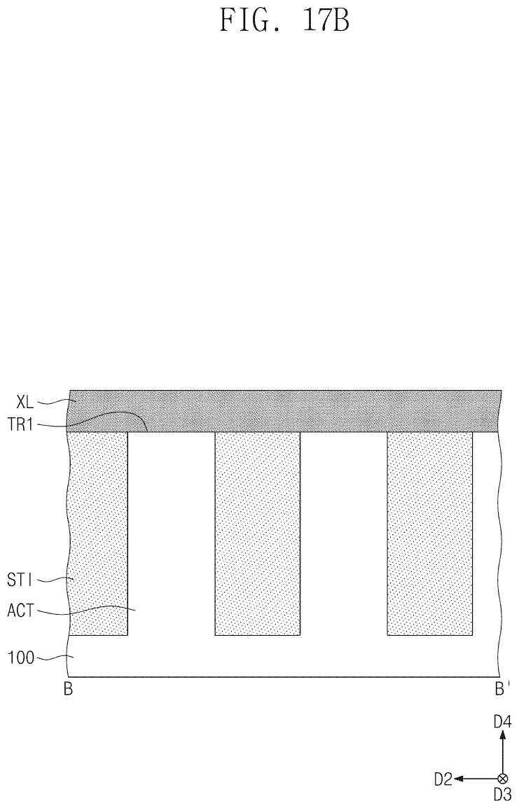

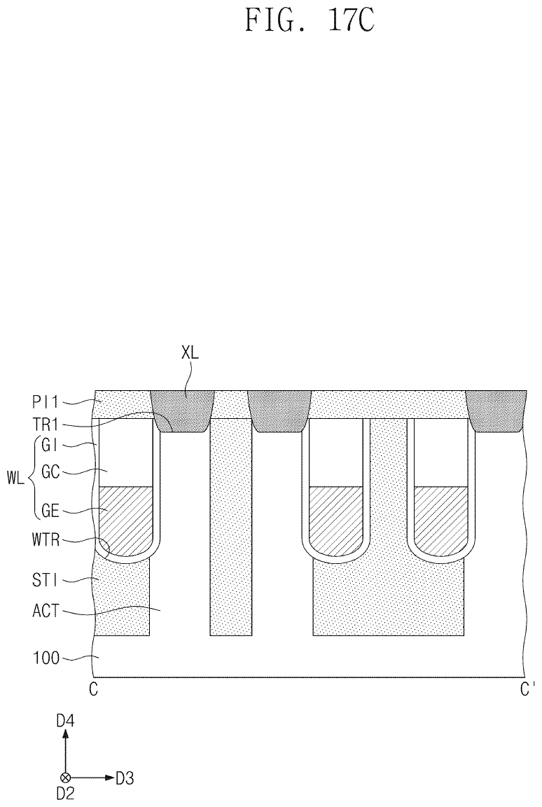

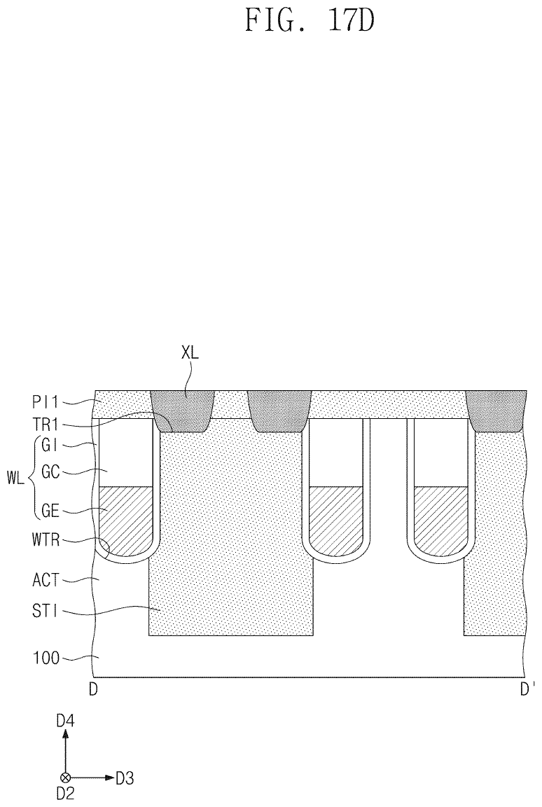

Referring to FIGS. 16 to 17D, a first pad insulating pattern PI1 may be formed on the active pattern ACT and the device isolation pattern STI. The formation of the first pad insulating pattern PI1 may include forming a first pad insulating layer (not shown) on an entire top surface of the substrate 100, and etching the first pad insulating layer by an anisotropic etching process to form first pad insulating patterns PI1 and first trench regions TR1. Each of the first pad insulating patterns PI1 and the first trench regions TR1 may extend in the second direction D2. The first and second edge portions EA1 and EA2 of the active patterns ACT may be exposed by the first trench regions TR1.

A width of the first trench region TR1 in the third direction D3 may be changed depending on a level. For example, the width of the first trench region TR1 in the third direction D3 may decrease as a level decreases.

Pad lines XL may be formed to fill the first trench regions TR1, respectively. The pad lines XL may extend in the second direction D2 in the first trench regions TR1. The pad lines XL may cover the exposed first and second edge portions EA1 and EA2 of the active patterns ACT.

The pad lines XL may be formed using an engraving process. In other words, the first pad insulating layer may be etched to form the first pad insulating patterns PI1 and the first trench regions TR1, and the first pad insulating patterns PI1 may be used as a mold for forming the pad lines XL. Since the first trench regions TR1 are formed by etching the first pad insulating layer, the width of the first trench region TR1 in the third direction D3 may be changed depending on a level. For example, the width of the first trench region TR1 in the third direction D3 may decrease as a level decreases. Thus, a width of the pad line XL in the third direction D3 may also decrease as a level decreases.

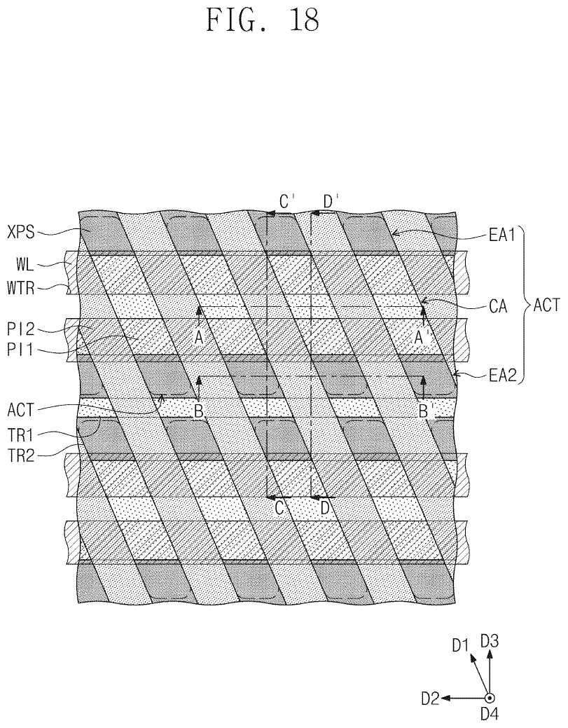

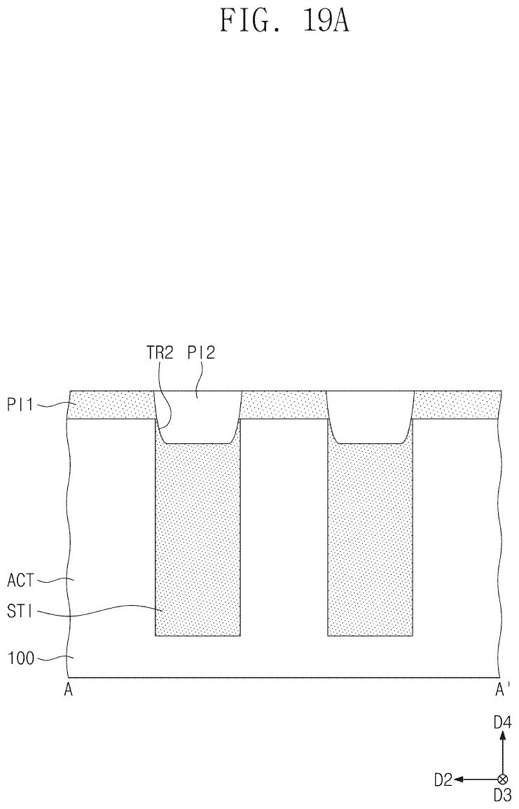

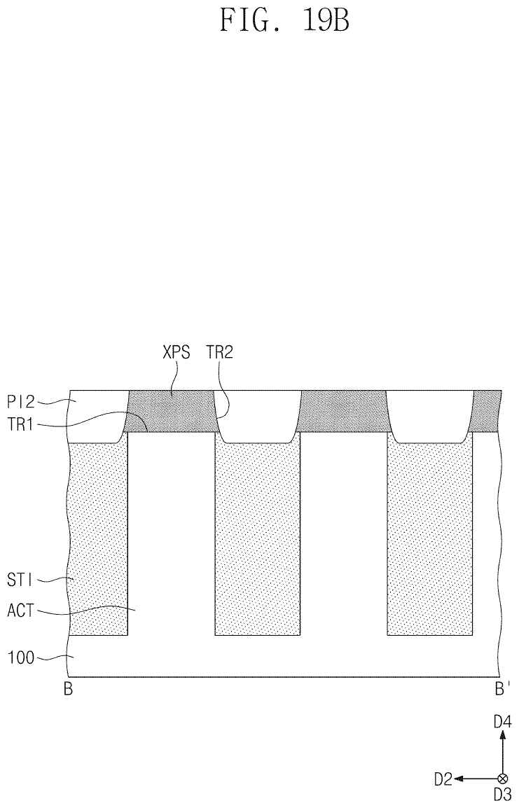

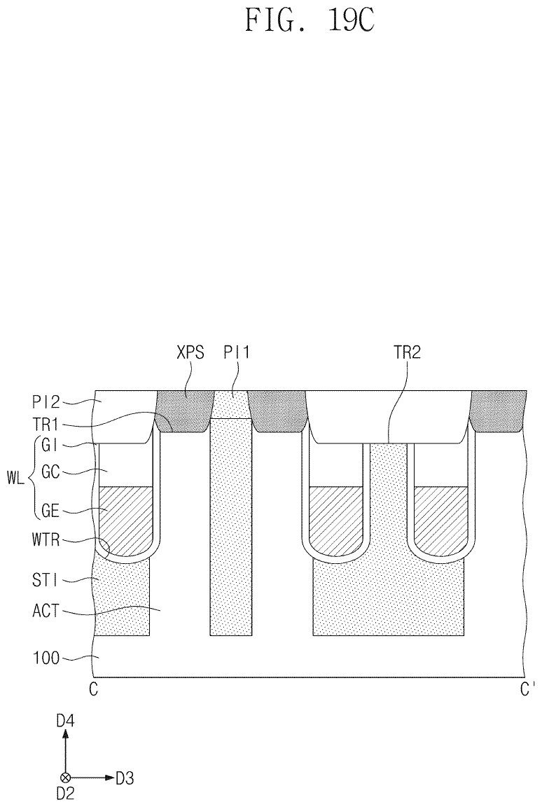

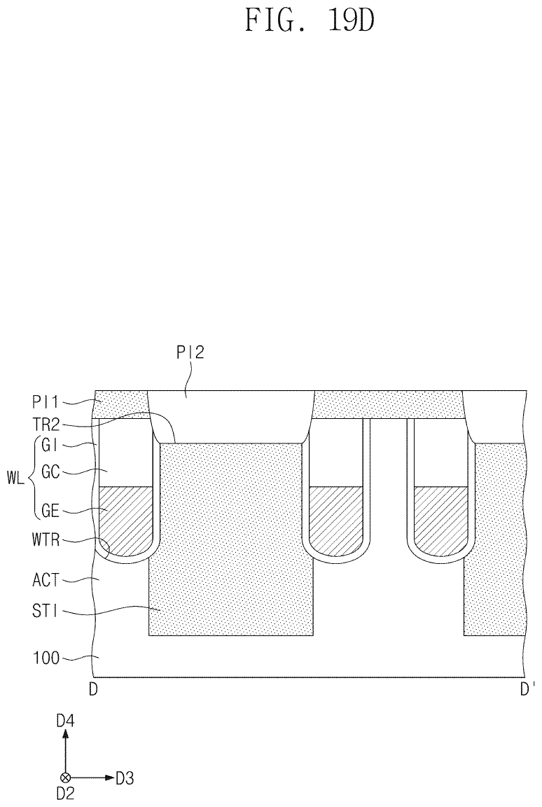

Referring to FIGS. 18 to 19D, storage node pads XPS may be formed by etching the pad lines XL. The etching of the pad lines XL may include forming second trench regions TR2 dividing each of the pad lines XL into a plurality of the storage node pads XPS. The second trench regions TR2 may extend in the first direction D1. The second trench regions TR2 may intersect the first pad insulating pattern PI1 in the first direction D1.

Second pad insulating patterns PI2 may be formed to fill the second trench regions TR2, respectively. The second pad insulating patterns PI2 may extend in the first direction D1 in the second trench regions TR2. The storage node pads XPS may cover the first and second edge portions EA1 and EA2 of the active patterns ACT.

The storage node pads XPS may be formed by an embossing process using the pad lines XL. In other words, the pad lines XL may be first formed, and then, each of the pad lines XL may be etched to form the storage node pads XPS. Since the second trench regions TR2 are formed by etching the pad lines XL, a width of the second trench region TR2 in the second direction D2 may be changed depending on a level. For example, the width of the second trench region TR2 in the second direction D2 may decrease as a level decreases. Thus, a width of the second pad insulating pattern PI2 in the second direction D2 may also decrease as a level decreases. On the contrary, a width of the storage node pad XPS in the second direction D2 may increase as a level decreases.

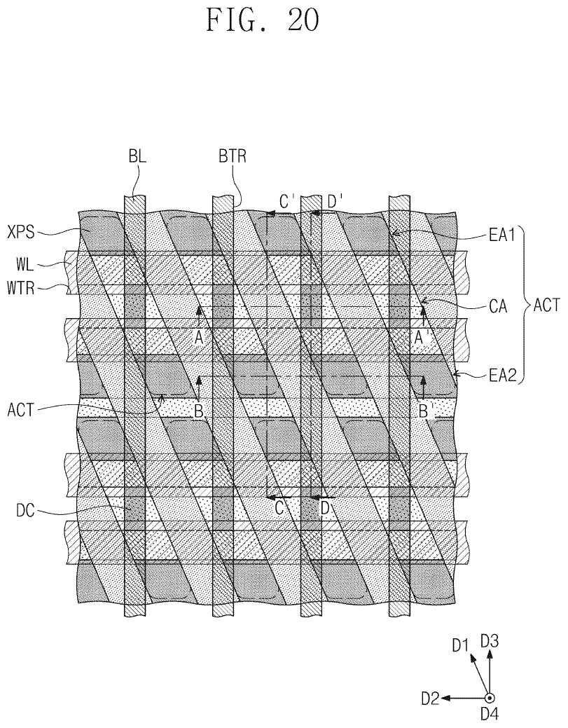

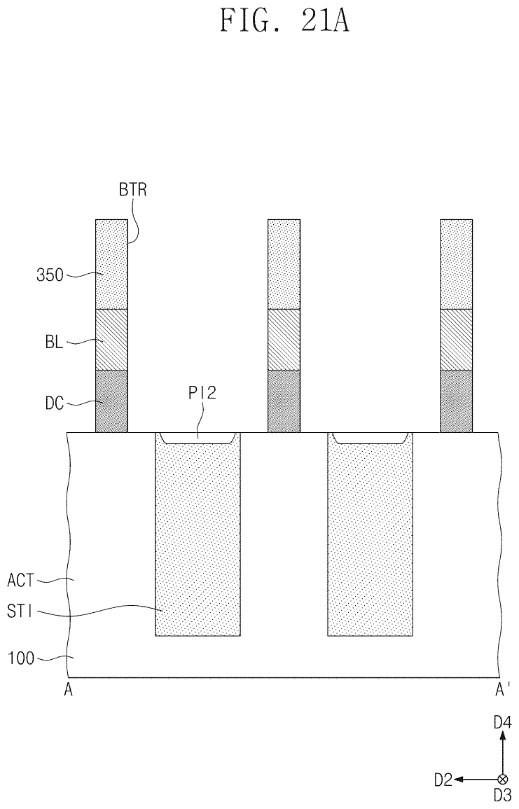

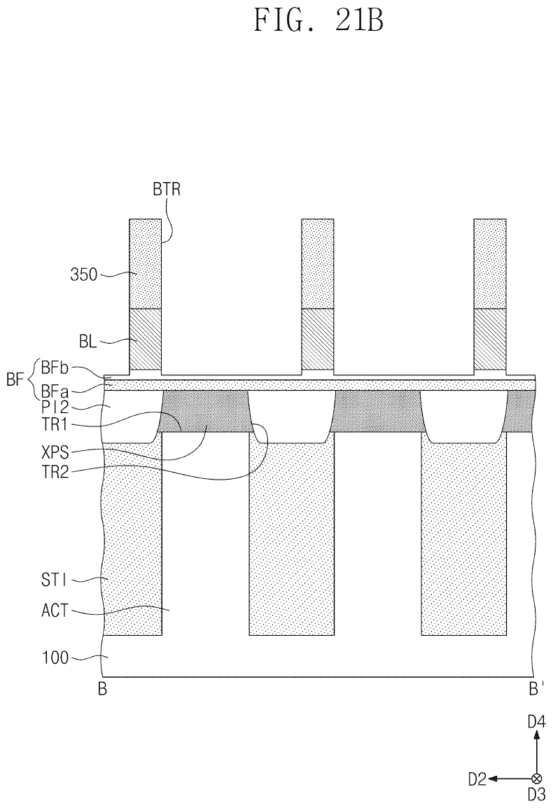

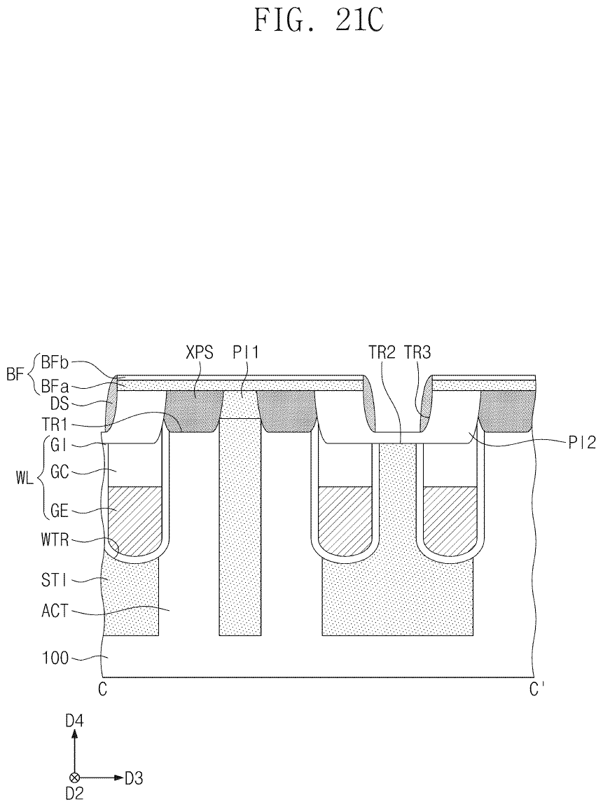

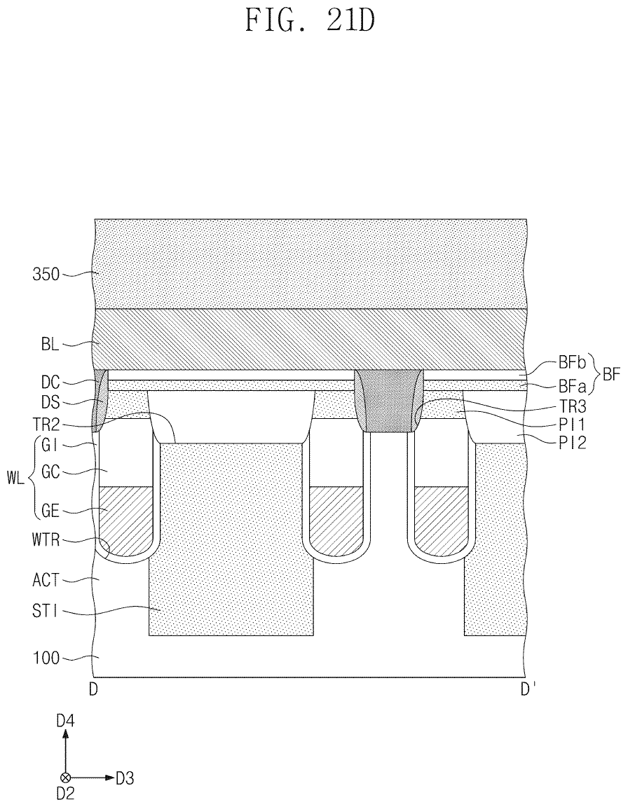

Referring to FIGS. 20 to 21D, a buffer layer BF may be formed to cover an entire top surface of the substrate 100. For example, the buffer layer BF may include a lower buffer layer BFa and an upper buffer layer BFb, but embodiments of the inventive concepts are not limited thereto.

Thereafter, the buffer layer BF and the first pad insulating pattern PI1 may be etched to form third trench regions TR3. The third trench regions TR3 may extend in the second direction D2 and may be spaced apart from each other in the third direction D3. The third trench regions TR3 may be formed on the center portions CA of the active patterns ACT. The center portions CA of the active patterns ACT may be exposed by the third trench regions TR3.

Bit line node contact spacers DS may be formed on inner side surfaces of the third trench regions TR3. A bit line contact layer (not shown) may be formed to fill the third trench regions TR3. A bit line layer (not shown) and a bit line capping layer (not shown) may be sequentially formed to cover an entire top surface of the substrate 100.

Thereafter, a bit line capping pattern 350, a bit line BL and a bit line node contact DC may be formed using an etching process. The bit line capping pattern 350, the bit line BL and the bit line node contact DC may be respectively formed from the bit line capping layer, the bit line layer and the bit line contact layer by the etching process. In this process, a portion of the buffer layer BF (e.g., a portion of the upper buffer layer BFb) may also be etched.

In the formation of the bit lines BL, bit line trench regions BTR may be formed between the bit lines BL. The bit line trench regions BTR may be spaced apart from each other in the second direction D2 and may extend in the third direction D3. The inner surfaces of the third trench regions TR3 may be exposed again through the bit line trench regions BTR.

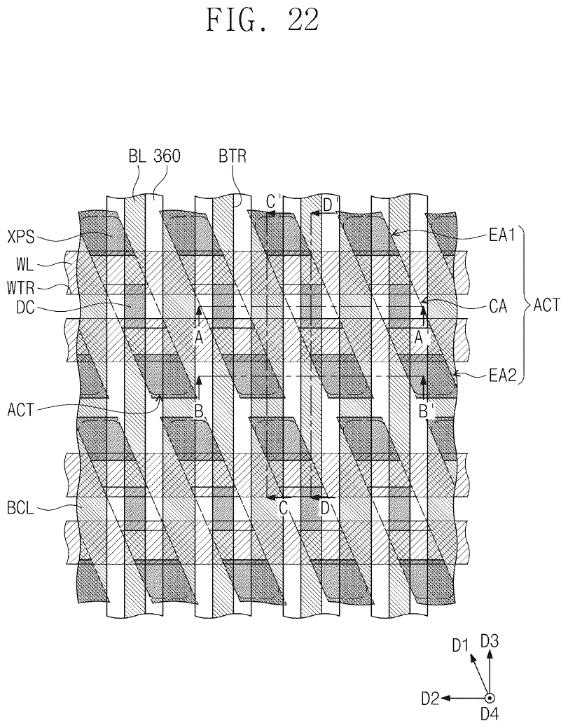

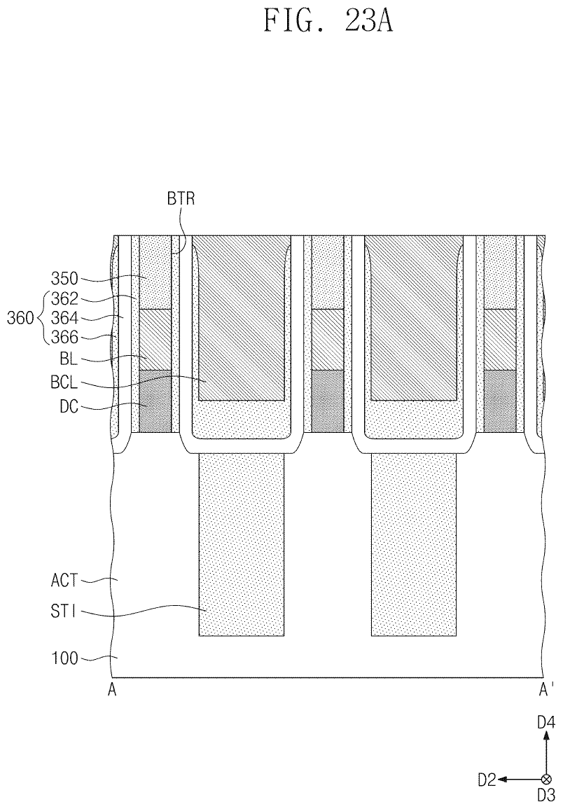

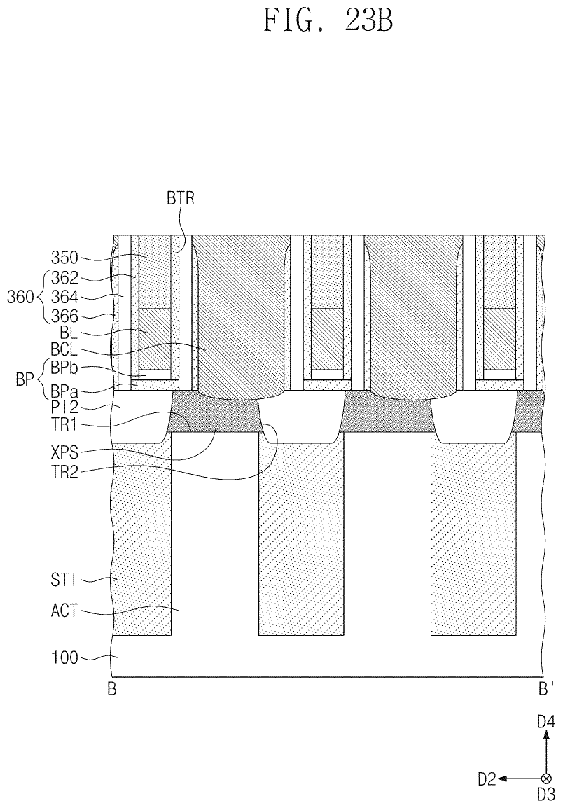

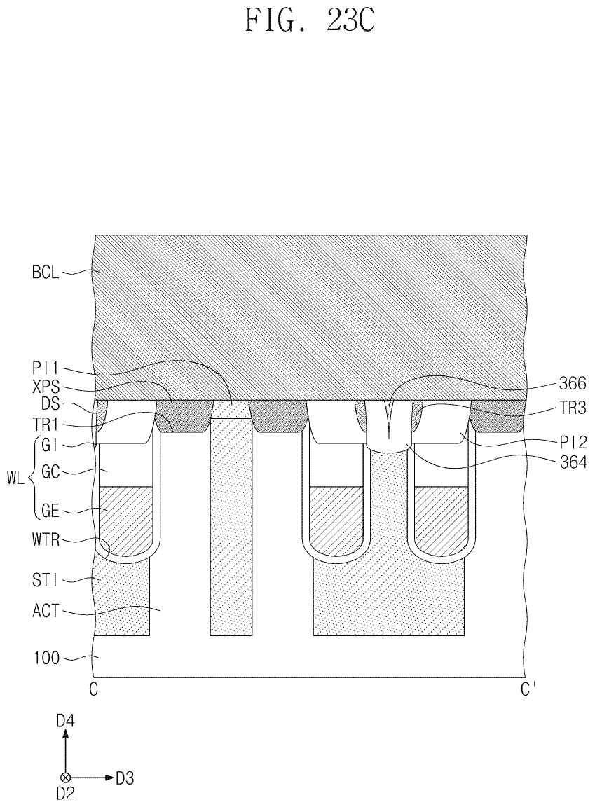

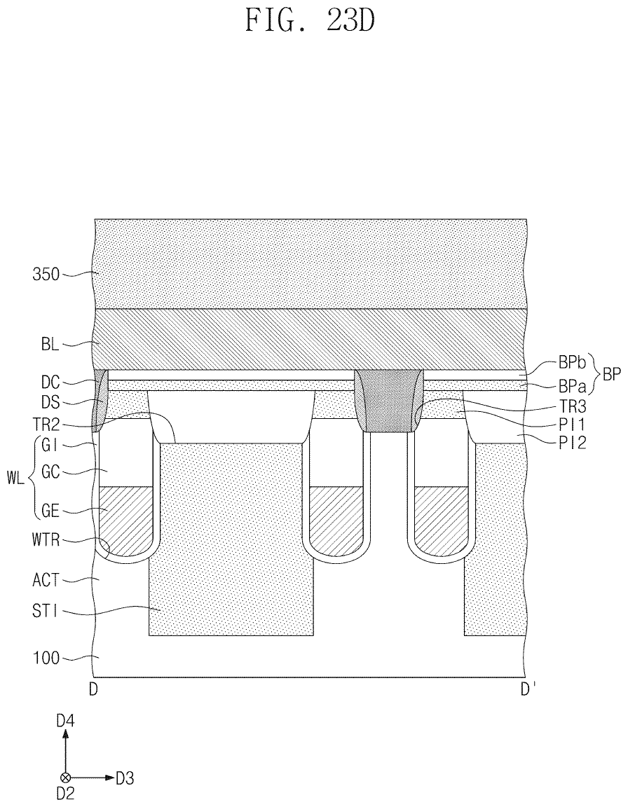

Referring to FIGS. 22 to 23D, a bit line spacer 360 may be formed on a side surface of the bit line BL. In FIG. 22, the first and second pad insulating patterns PI1 and PI2 and the third trench regions TR3 of FIG. 20 are omitted for the purpose of ease and convenience in explanation and illustration. The formation of the bit line spacer 360 may include sequentially forming a first spacer 362, a second spacer 364 and a third spacer 366, which conformally cover side surfaces of the bit line BL and the bit line capping pattern 350.

The formation of the first spacer 362 may include conformally depositing the first spacer 362 on an inner surface of the bit line trench region BTR and the buffer layer BF, and etching the first spacer 362 on the buffer layer BF and the buffer layer BF by using the bit line capping pattern 350 as an etch mask. The buffer layer BF remaining under the bit line capping pattern 350 may not be removed but may be formed into a buffer pattern BP. The storage node pads XPS may be exposed by the etching process performed on the buffer layer BF.

The formation of the second spacer 364 and the third spacer 366 may include conformally depositing the second spacer 364 on the inner surface of the bit line trench region BTR and the storage node pads XPS, etching the second spacer 364 on the storage node pads XPS, conformally depositing the third spacer 366 on the second spacer 364 and the storage node pads XPS, and etching the third spacer 366 on the storage node pads XPS. In the formation of the second and third spacers 364 and 366, the storage node pads XPS may be finally exposed. For example, the third spacer 366 may be thickly formed on the inner surface of the third trench region TR3 due to a narrow width of the third trench region TR3, but embodiments of the inventive concepts are not limited thereto.

Thereafter, storage node lines BCL may be formed to fill remaining portions of the bit line trench regions BTR, respectively. The storage node lines BCL may be spaced apart from each other in the second direction D2 and may extend in the third direction D3 in the bit line trench regions BTR.

The formation of the storage node lines BCL may include forming a storage node layer (not shown) covering the inner surfaces of the bit line trench regions BTR and the bit line capping patterns 350, and etching an upper portion of the storage node layer to divide the storage node layer into the storage node lines BCL. The etching of the upper portion of the storage node layer may include performing a polishing process on the upper portion of the storage node layer and an upper portion of the bit line capping pattern 350. Thus, a top surface of the storage node line BCL and a top surface of the bit line capping pattern 350 may be located at the same or substantially the same level and may be coplanar or substantially coplanar with each other.

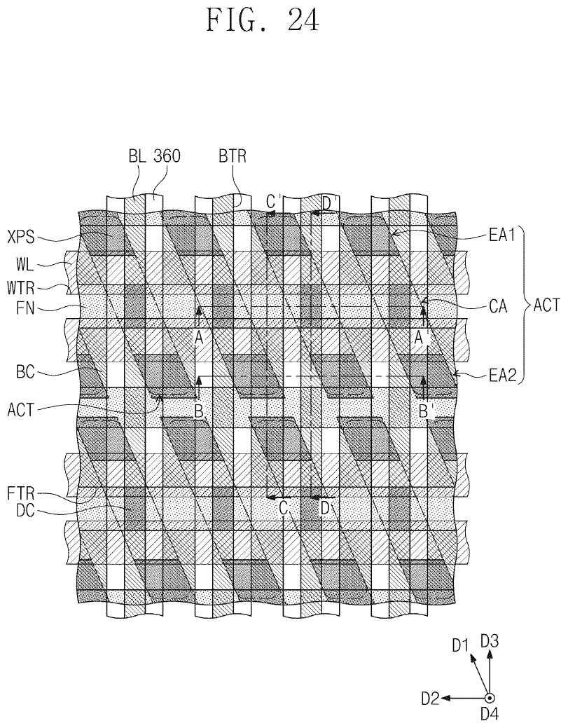

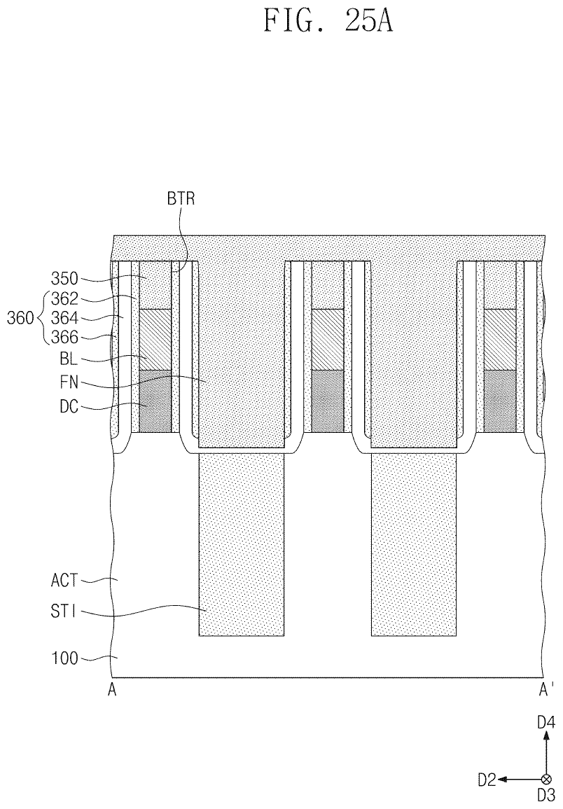

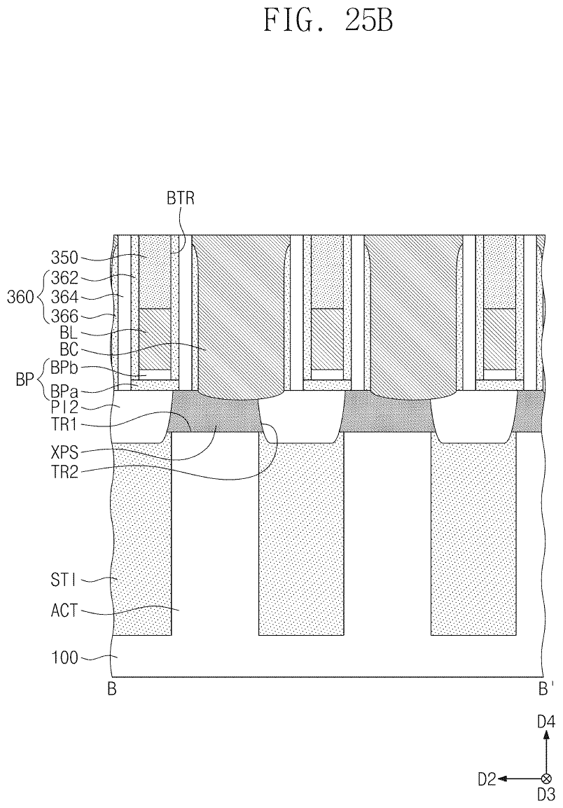

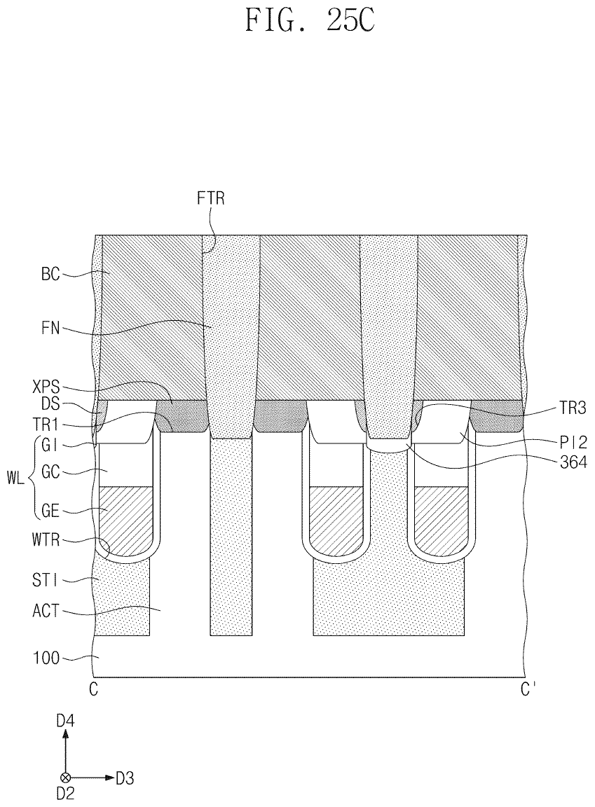

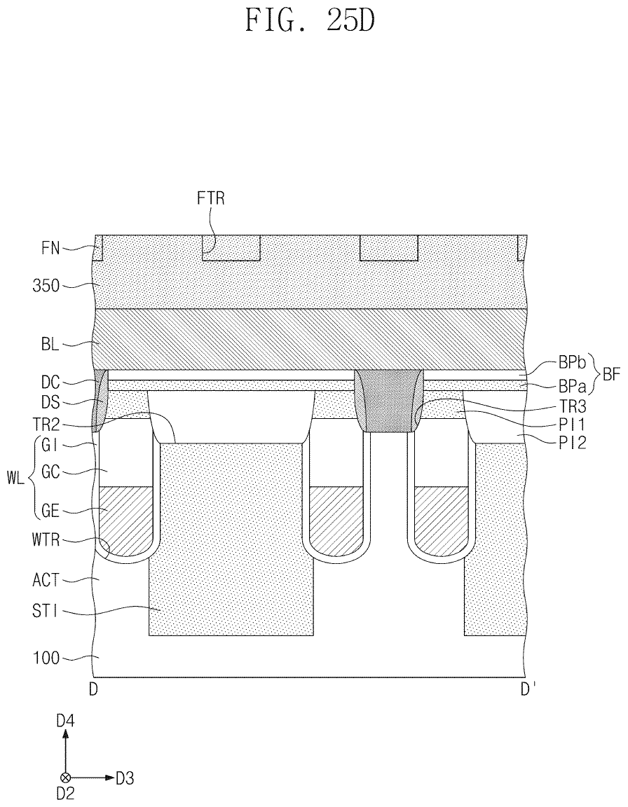

Referring to FIGS. 24 to 25D, storage node contacts BC may be formed in the bit line trench regions BTR. The formation of the storage node contacts BC may include dividing each of the storage node lines BCL into a plurality of the storage node contacts BC by an etching process. Each of the storage node lines BCL may be divided into the storage node contacts BC by fence trench regions FTR. The fence trench regions FTR may extend in the second direction D2 and may be spaced apart from each other in the third direction D3.

In the etching process, the storage node lines BCL and the bit line capping pattern 350 may be etched, and a bottom surface of the fence trench region FTR may have a groove due to an etch selectivity thereof. More particularly, a bottom surface of the fence trench region FTR formed between the bit lines BL may be formed at a lower level than a bottom surface of the fence trench region FTR formed on the bit line capping pattern 350.

Each of the fence trench regions FTR may include lower regions disposed between the bit lines BL and arranged in a line in the second direction D2, and an upper region of the fence trench region FTR may be provided on the bit lines BL so as to be connected to the lower regions. A bottommost surface of the fence trench region FTR may be lower than a bottommost surface of the storage node contact BC.

Thereafter, fence patterns FN may be formed to fill the fence trench regions FTR. The formation of the fence patterns FN may include forming a fence layer (not shown) filling the fence trench regions FTR and covering top surfaces of the storage node contacts BC, and removing an upper portion of the fence layer to divide the fence layer into a plurality of the fence patterns FN.

The storage node contacts BC may be formed by an embossing process using the storage node lines BCL. In other words, the storage node lines BCL may be first formed, and then, the storage node contacts BC may be formed by etching each of the storage node lines BCL. Since the fence trench regions FTR are formed by etching the storage node lines BCL, a width of the fence trench region FTR in the third direction D3 may be changed depending on a level. For example, the width of the fence trench region FTR in the third direction D3 may decrease as a level decreases. Thus, a width of the fence pattern FN in the third direction D3 may also decrease as a level decreases.

For example, in the etching of the storage node lines BCL, the storage node line BCL adjacent to the bit line spacer 360 may not be completely etched, but a portion of the storage node line BCL may remain along a side surface of the bit line spacer 360. Thus, the storage node contact BC may have a protrusion protruding between the fence pattern FN and the bit line BL. In addition, a corner of the fence pattern FN may be rounded. However, example embodiments of the inventive concepts are not limited thereto.

According to the inventive concepts, the storage node contacts BC may be formed using the embossing process. In other words, the storage node lines BCL may be formed prior to the formation of the storage node contacts BC. In this case, the storage node lines BCL may be easily formed in the wide bit line trench regions BTR, as compared with a case of forming the storage node contacts BC between the fence patterns FN after formation of the fence patterns FN (for example, an engraving process). Finally, the storage node contacts BC may be formed, for example, more easily formed during manufacturing, and thus electrical characteristics and reliability of the semiconductor device may be improved.

Referring again to FIGS. 1 to 3D, an upper portion of the storage node contact BC may be removed. The removing of the upper portion of the storage node contact BC may include performing an etch-back process on the upper portion of the storage node contact BC. Thus, a top surface of the storage node contact BC may be formed at the second level LV2.

Landing pads LP may be formed on the storage node contacts BC. The formation of the landing pads LP may include sequentially forming a landing pad layer (not shown) and mask patterns (not shown) which cover the top surfaces of the storage node contacts BC, and dividing the landing pad layer into a plurality of the landing pads LP by an anisotropic etching process using the mask patterns as etch masks.

In some example embodiments, the second spacer 364 may be exposed by the anisotropic etching process of the landing pad layer. An etching process may further be performed on the second spacer 364 through the exposed portion of the second spacer 364, and finally, the second spacer 364 may include an air gap. However, example embodiments of the inventive concepts are not limited thereto.

Thereafter, a filling pattern 440 may be formed in an empty region formed by the removal of the landing pad layer. The filling pattern 440 may be formed to surround each of the landing pads LP in a plan view. A data storage pattern DSP may be formed on each of the landing pads LP.

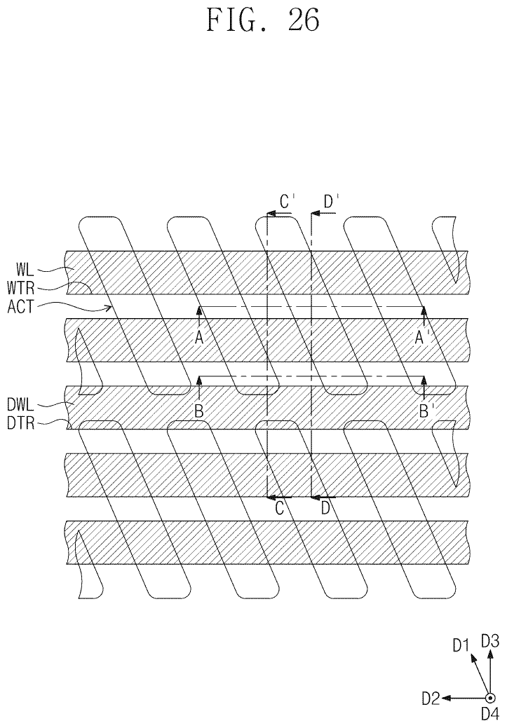

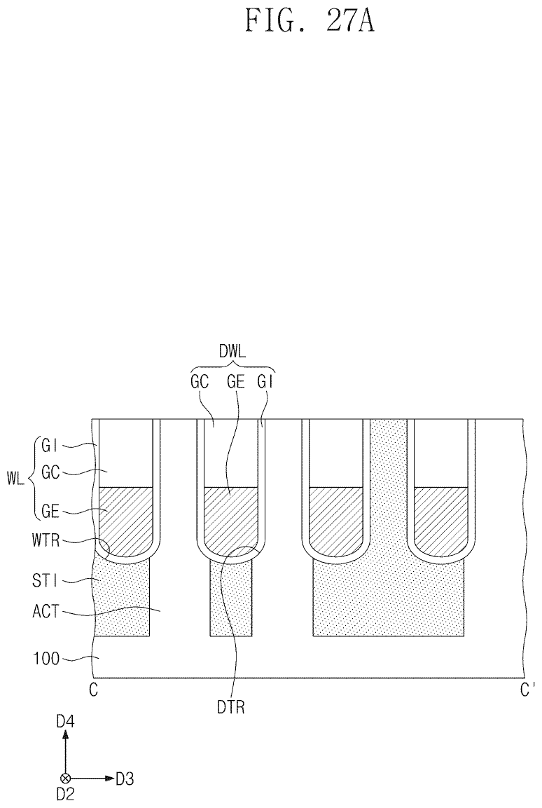

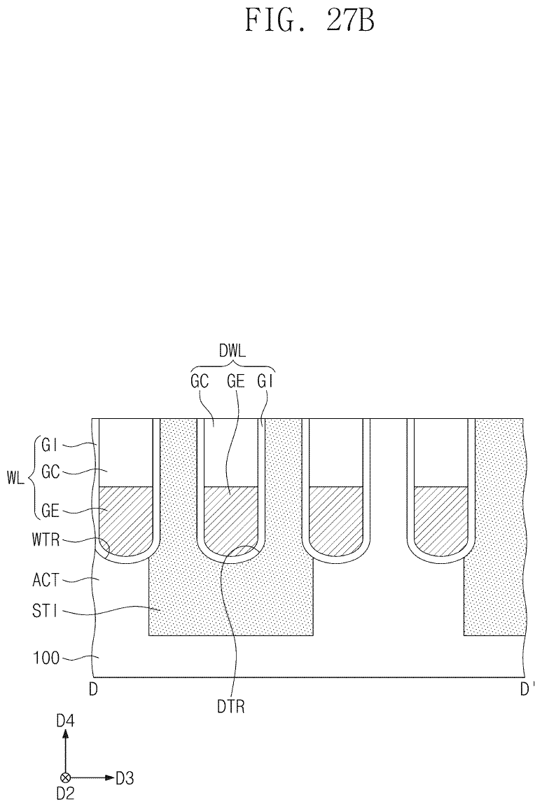

FIGS. 26 to 27B are views illustrating a method of manufacturing the semiconductor device of FIGS. 5 to 6B.

Referring to FIGS. 26 to 27B, a dummy word line DWL may be formed together with the word line WL described with reference to FIGS. 14 to 15D. The formation of the dummy word line DWL may include forming a dummy word line trench region DTR together with the word line trench region WTR, conformally depositing a gate dielectric pattern GI on an inner surface of the dummy word line trench region DTR, filling the dummy word line trench region DTR with a conductive layer, performing an etch-back process and/or a polishing process on the conductive layer to form a gate electrode GE, and forming a gate capping pattern GC filling a remaining portion of the dummy word line trench region DTR on the gate electrode GE.

Thereafter, the semiconductor device described with reference to FIGS. 5 to 6B may be manufactured using the aforementioned method of manufacturing a semiconductor device.

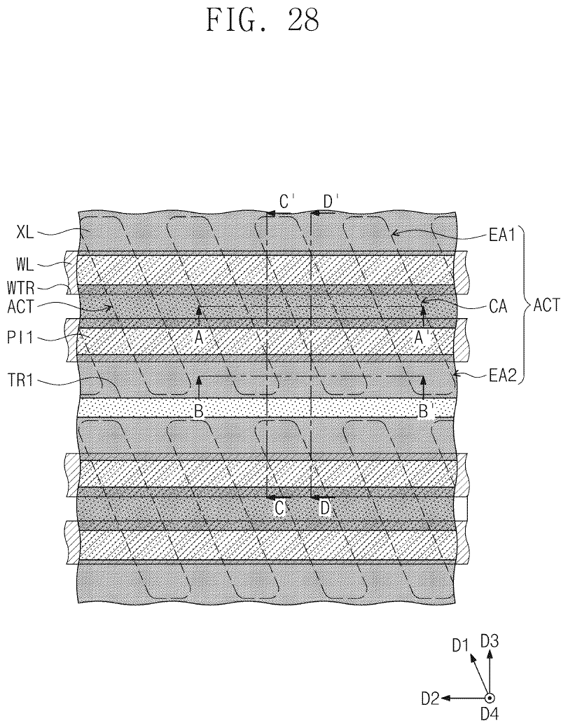

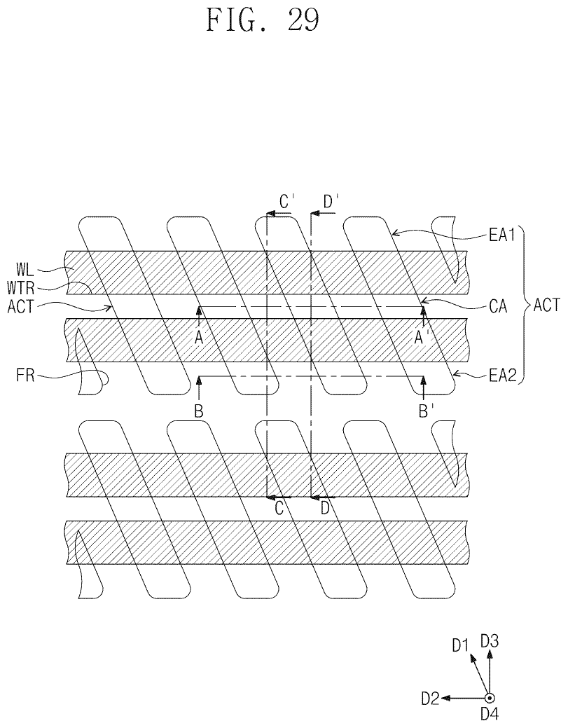

FIG. 28 is a plan view illustrating a method of manufacturing the semiconductor device of FIG. 7.

Referring to FIG. 28, in the formation of the first trench regions TR1 described with reference to FIGS. 16 to 17D, the first trench regions TR1 may further be formed on the center portions CA of the active patterns ACT. The center portions CA of the active patterns ACT may be exposed by the first trench regions TR1.

The pad lines XL may further be formed on the center portions CA of the active patterns ACT. The pad lines XL may fill the first trench regions TR1 on the center portions CA of the active patterns ACT. Each of the pad lines XL on the center portions CA of the active patterns ACT may be divided into bit line node pads XPB by the formation of the second pad insulating patterns PI2.

Thereafter, the semiconductor device described with reference to FIG. 7 may be manufactured using the aforementioned method of manufacturing a semiconductor device.

FIGS. 29 to 32D are views illustrating a method of manufacturing the semiconductor device of FIGS. 8 to 9D.

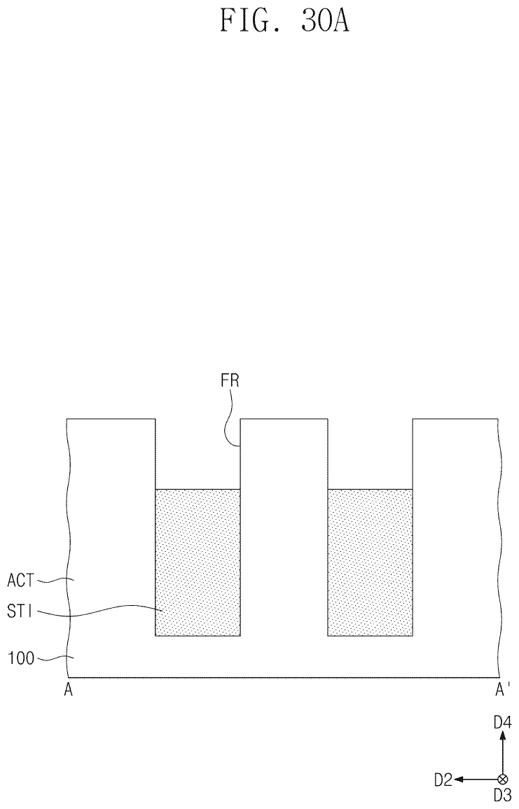

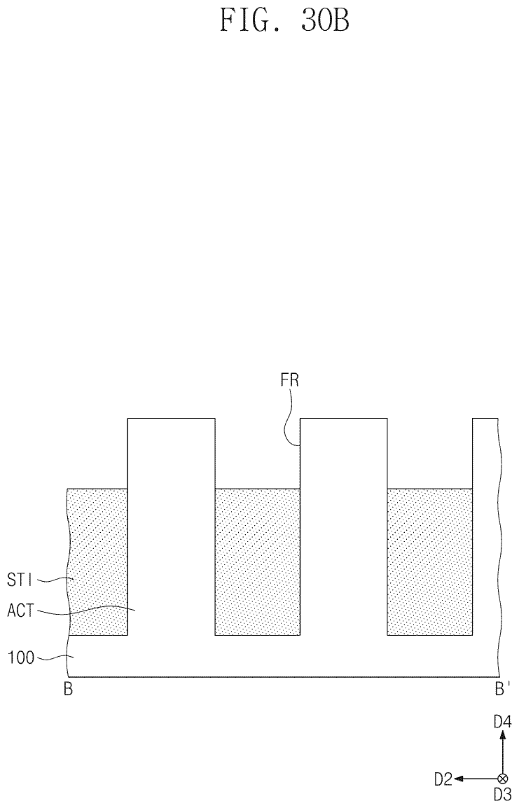

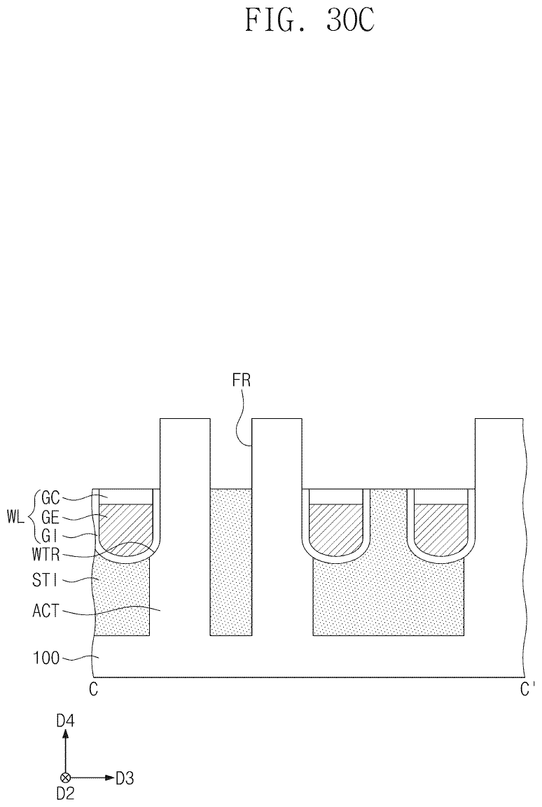

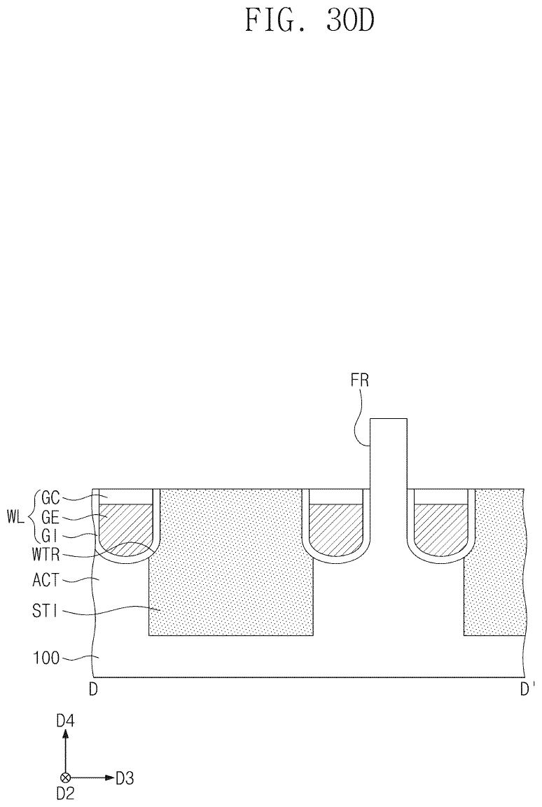

Referring to FIGS. 29 to 30D, after the formation of the word lines WL described with reference to FIGS. 14 to 15D, an upper portion of the device isolation pattern STI and an upper portion of the word line WL (e.g., an upper portion of the gate capping pattern GC) may be removed, and a field recess region FR may be formed. The field recess region FR may be a region surrounded by upper portions of the active patterns ACT. The upper portions of the active patterns ACT may be portions of the active patterns ACT, which are located at a level higher than a top surface of the device isolation pattern STI and a top surface of the word line WL. Side surfaces of the upper portions of the active patterns ACT may be exposed by the field recess region FR.

The removal of the upper portion of the device isolation pattern STI and the upper portion of the word line WL may be performed using an etch recipe having an etch selectivity with respect to the active patterns ACT. Thus, even though an exposure process for a patterning process is not performed, the upper portion of the device isolation pattern STI and the upper portion of the word line WL may be selectively removed. In addition, the upper portions of the active patterns ACT may remain.

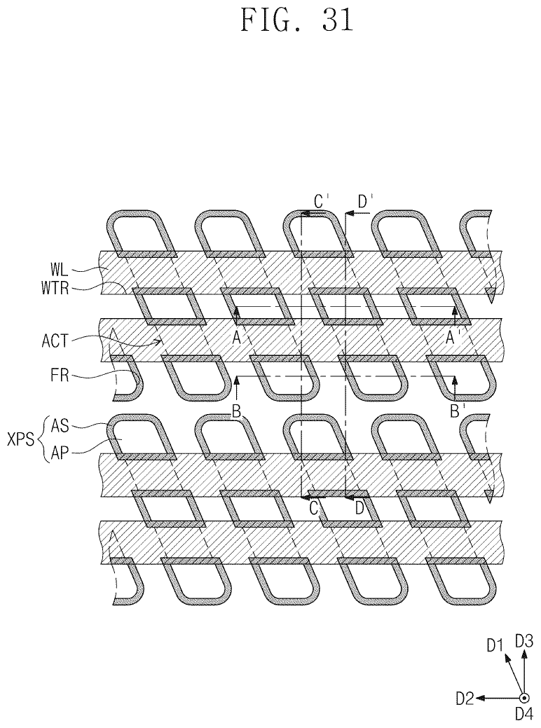

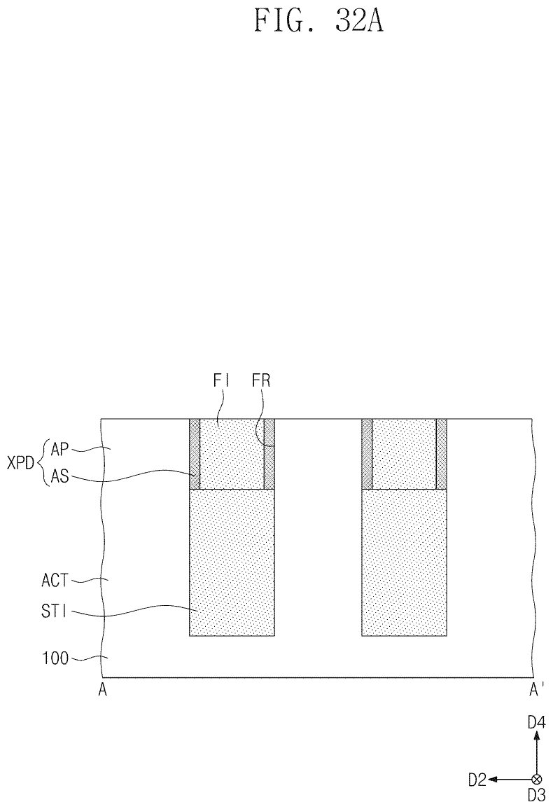

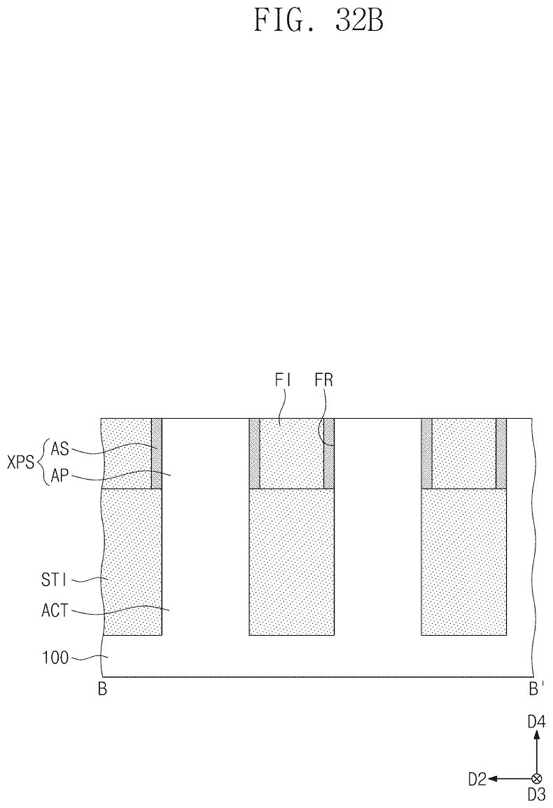

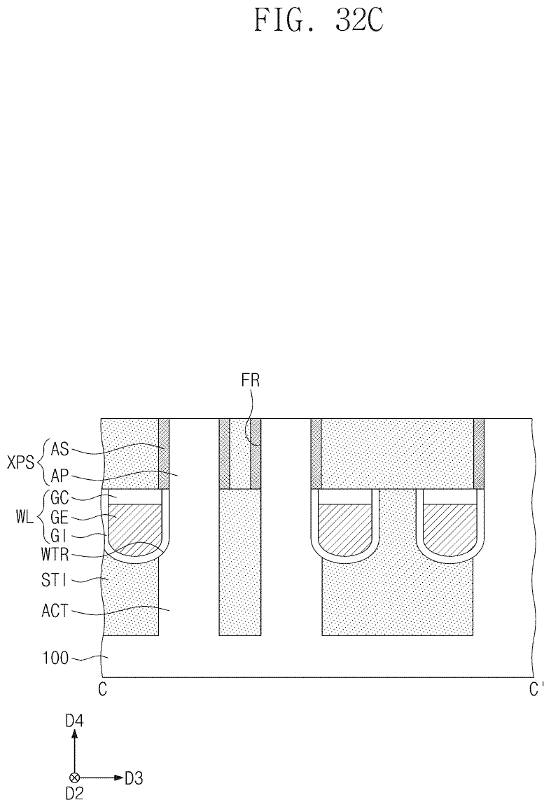

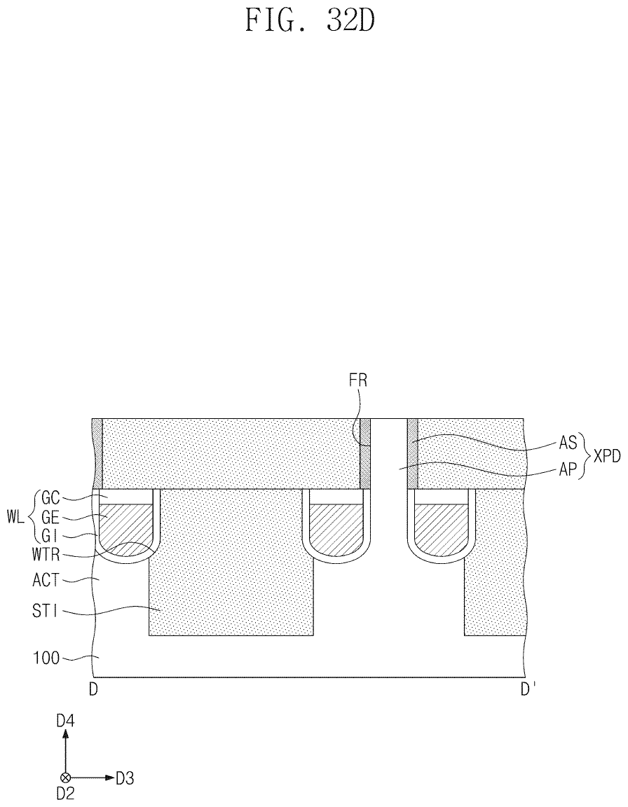

Referring to FIGS. 31 to 32D, a storage node pad XPS and a bit line node pad XPB may be formed. The formation of the storage node pad XPS and the bit line node pad XPB may include forming active spacers AS surrounding the side surfaces of the upper portions of the active patterns ACT. Here, the upper portions of the active patterns ACT, which are surrounded by the active spacers AS, may be defined as active pads AP.

A filling insulation pattern FI may be formed in the field recess region FR. The filling insulation pattern FI may be formed to fill a remaining portion of the field recess region FR. The formation of the filling insulation pattern FI may include forming a filling insulation layer (not shown) covering an entire top surface of the substrate 100, and removing an upper portion of the filling insulation layer to form the filling insulation pattern FI. A top surface of the storage node pad XPS and a top surface of the bit line node pad XPB may be exposed by the removal of the upper portion of the filling insulation layer.

In the case of using the manufacturing method described with reference to FIGS. 29 to 32D, the process of forming the storage node pad XPS described with reference to FIGS. 16 to 19D may be omitted. Thereafter, the semiconductor device described with reference to FIGS. 8 to 9D may be manufactured using the aforementioned method of manufacturing a semiconductor device.

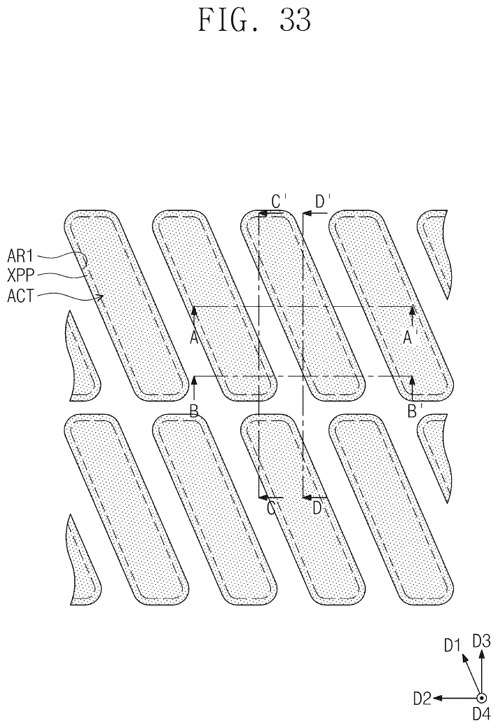

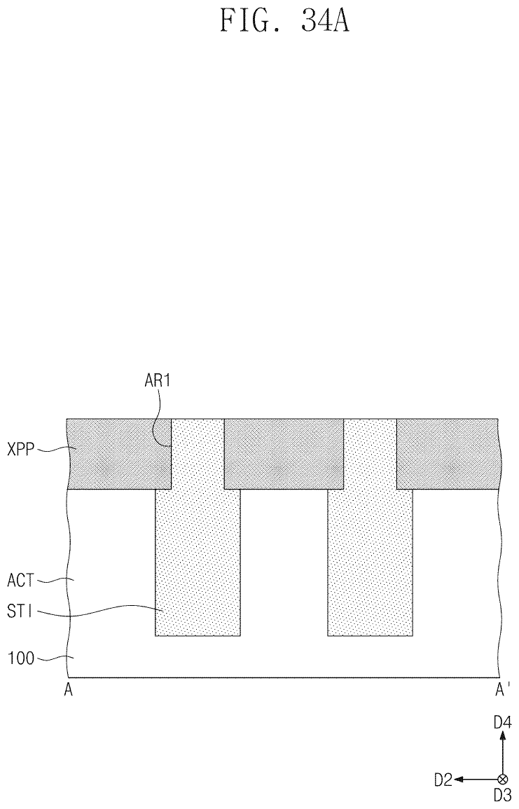

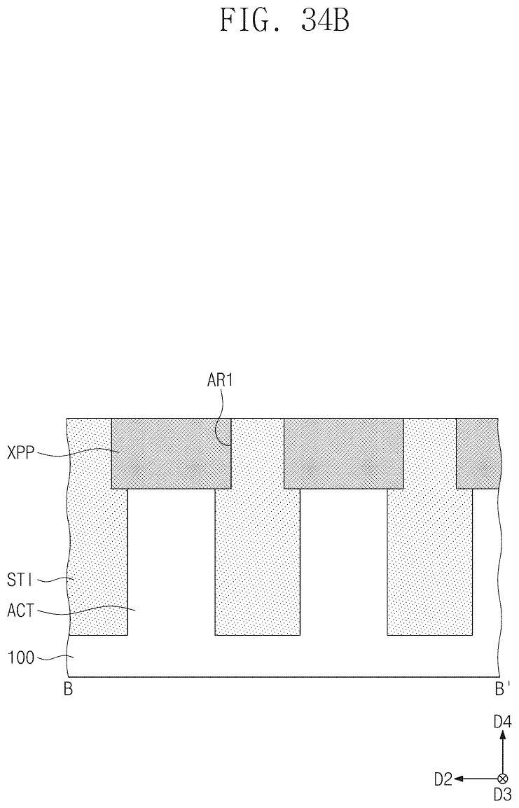

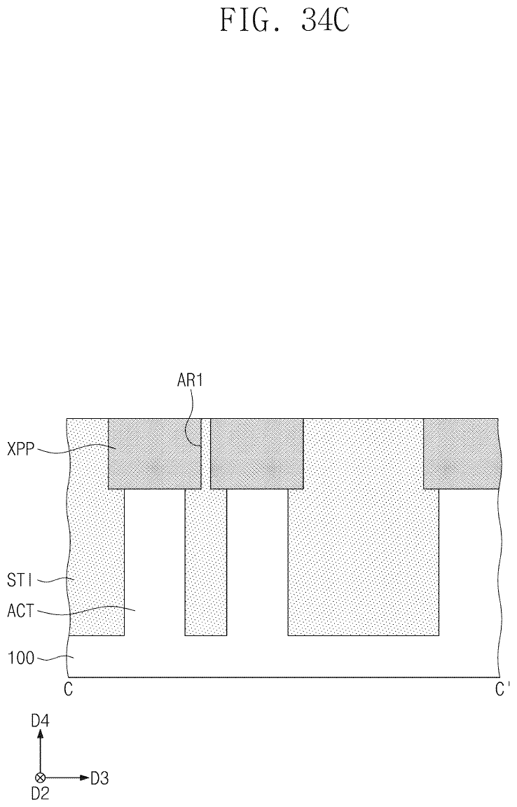

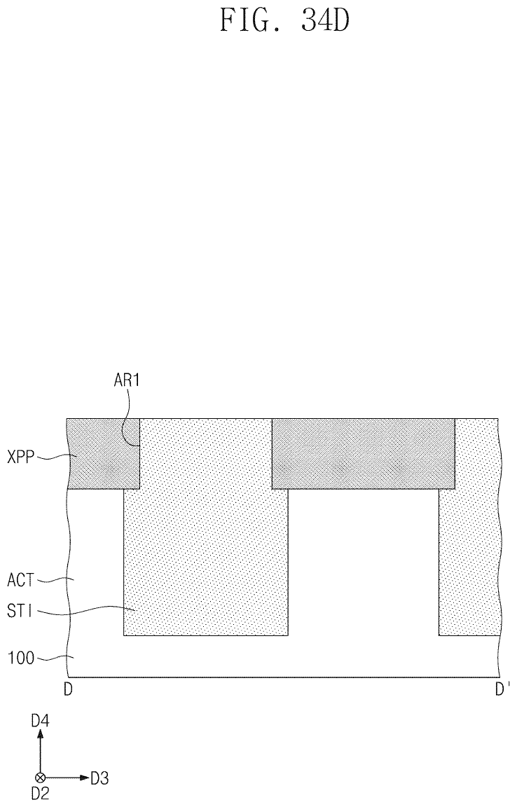

FIGS. 33 to 34D are views illustrating a method of manufacturing the semiconductor device of FIGS. 10 to 11D.

Referring to FIGS. 33 to 34D, after the formation of the active patterns ACT and the device isolation pattern STI described with reference to FIGS. 14 to 15D, upper portions of the active patterns ACT may be removed. Thus, first active recess regions AR1 may be formed. The first active recess regions AR1 may be regions surrounded by an upper portion of the device isolation pattern STI.

The removal of the upper portions of the active patterns ACT may be performed using an etch recipe having an etch selectivity with respect to the device isolation pattern STI. Thus, even though an exposure process for a patterning process is not performed, the upper portions of the active patterns ACT may be selectively removed. In addition, the upper portion of the device isolation pattern STI may remain.

Thereafter, each of the first active recess regions AR1 may be horizontally expanded. In this process, a portion of the upper portion of the device isolation pattern STI may be removed. The first active recess regions AR1 may expose top surfaces of the active patterns ACT, respectively.

Preliminary node pads XPP may be formed in the first active recess regions AR1, respectively. For example, the preliminary node pads XPP may fill the first active recess regions AR1. The preliminary node pads XPP may be formed on the active patterns ACT. For example, the preliminary node pads XPP may completely cover the top surfaces of the active patterns ACT. Each of the preliminary node pads XPP may extend in the first direction D1, and the preliminary node pads XPP may be spaced apart from each other in the second and third directions D2 and D3.

Next, the word lines WL may be formed using the method described with reference to FIGS. 14 to 15D. Each of the preliminary node pads XPP may be divided into two storage node pads XPS and one bit line node pad XPB by a pair of the word lines WL. Thus, in the case of using the manufacturing method described with reference to FIGS. 33 to 34D, the process of forming the storage node pad XPS described with reference to FIGS. 16 to 19D may be omitted. Thereafter, the semiconductor device described with reference to FIGS. 10 to 11D may be manufactured using the aforementioned method of manufacturing a semiconductor device.

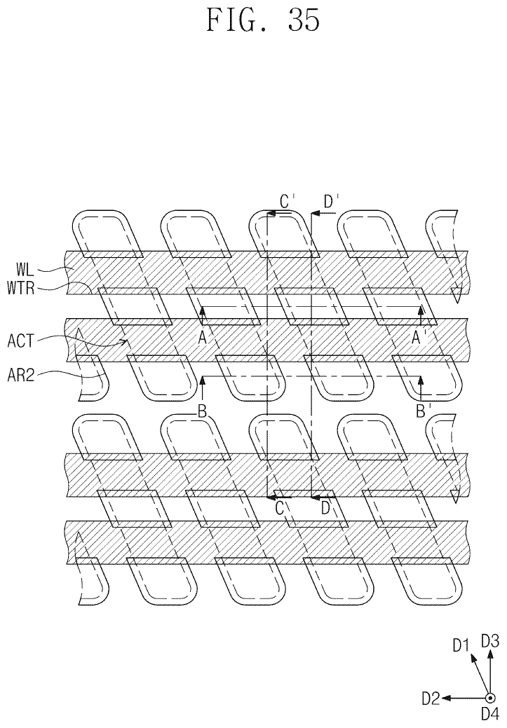

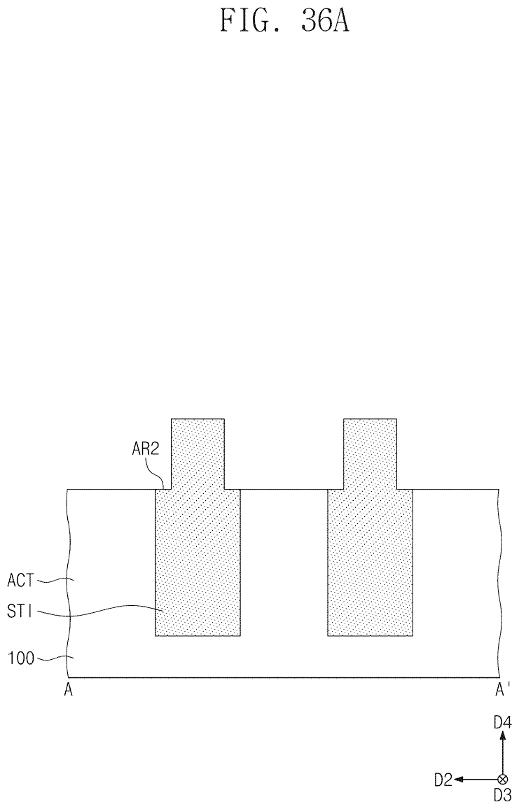

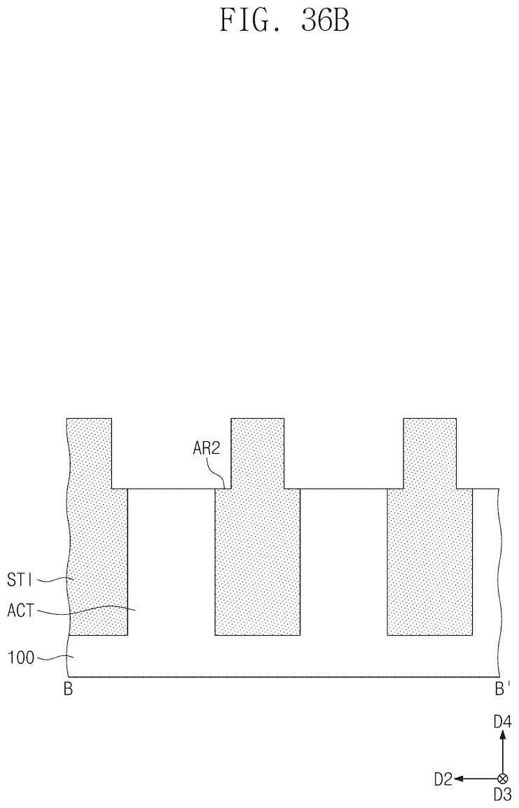

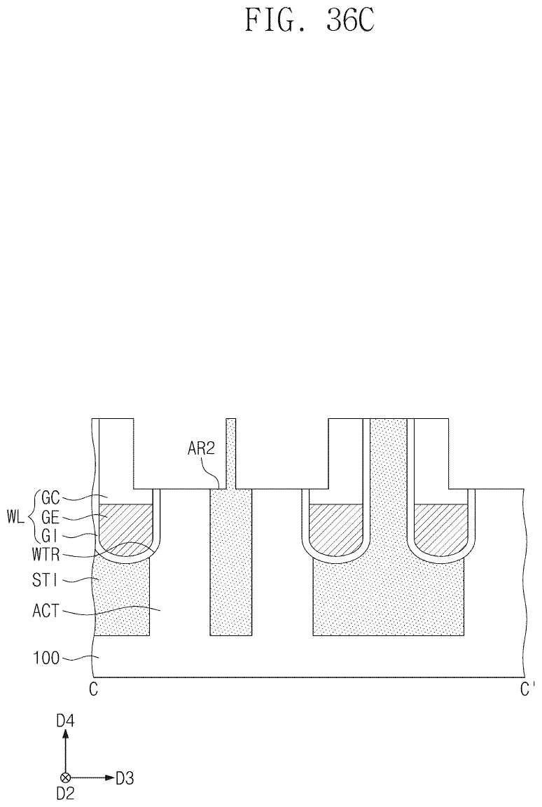

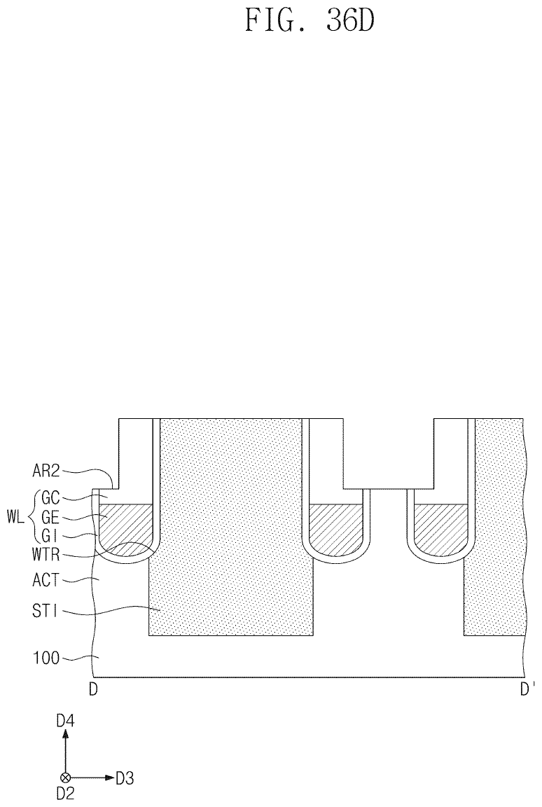

FIGS. 35 to 36D are views illustrating a method of manufacturing the semiconductor device of FIGS. 12 to 13D.

Referring to FIGS. 35 to 36D, after the formation of the word lines WL described with reference to FIGS. 14 to 15D, upper portions of the active patterns ACT may be removed, and second active recess regions AR2 may be formed. The second active recess region AR2 may be a region surrounded by an upper portion of the device isolation pattern STI and an upper portion of the word line WL.

The removal of the upper portions of the active patterns ACT may be performed using an etch recipe having an etch selectivity with respect to the device isolation pattern STI and the word line WL. Thus, even though an exposure process for a patterning process is not performed, the upper portions of the active patterns ACT may be selectively removed. In addition, the upper portion of the device isolation pattern STI and the upper portion of the word line WL may remain.

Thereafter, each of the second active recess regions AR2 may be horizontally expanded. In this process, the upper portion of the device isolation pattern STI and the upper portion of the word line WL may be partially removed. The second active recess regions AR2 may expose top surfaces of the active patterns ACT. For example, the first and second edge portions EA1 and EA2 and the center portion CA of the active pattern ACT may be exposed by the second active recess regions AR2, respectively.

Referring to FIGS. 12 to 13D, storage node pads XPS and bit line node pads XPB may be formed to fill the second active recess regions AR2. Thus, in the case of using the manufacturing method described with reference to FIGS. 35 to 36D, the process of forming the storage node pad XPS described with reference to FIGS. 16 to 19D may be omitted. Thereafter, the semiconductor device described with reference to FIGS. 12 to 13D may be manufactured using the aforementioned method of manufacturing a semiconductor device.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

According to the inventive concepts, the arrangement of the components in the semiconductor device may be simplified. As a result, difficulty of a patterning process, etc. of manufacturing the semiconductor device may be reduced to manufacture the semiconductor device, for example, more easily manufacture or having simpler manufacturing. In addition, the components may be relatively simply arranged to improve the integration density of the semiconductor device.

Furthermore, the storage node contacts may be formed (for example, more easily formed) using the embossing process, and thus the electrical characteristics and reliability of the semiconductor device may be improved.

While the example embodiments of the inventive concepts have been particularly shown and described, it will be understood by one of ordinary skill in the art that variations in form and detail may be made therein without departing from the spirit and scope of the attached claims.

1. A semiconductor device comprising:
a first active pattern and a second active pattern extending in a first direction and adjacent to each other in a second direction, the second direction intersecting the first direction, the first and second active patterns, each including a first edge portion and a second edge portion spaced apart from each other in the first direction;
a first storage node pad and a first storage node contact sequentially provided on the first edge portion of the first active pattern;
a second storage node pad and a second storage node contact sequentially provided on the second edge portion of the second active pattern; and
a fence pattern between the first storage node contact and the second storage node contact,
a bottom surface and a top surface of the first storage node contact located at a first level and a second level, respectively, and
a width of the fence pattern in a third direction, the third direction intersecting the first and second directions, the width of the fence pattern at the first level being less than a width of the fence pattern in the third direction at the second level.

2. The semiconductor device of claim 1, wherein a width of the fence pattern in the third direction decreases as a level decreases.

3. The semiconductor device of claim 1, wherein the first storage node pad includes a same material as the first storage node contact.

4. The semiconductor device of claim 1, wherein the first storage node contact includes dopant-doped poly-silicon.

5. The semiconductor device of claim 1, wherein the fence pattern is in contact with the first storage node contact and the second storage node contact.

6. (canceled)

7. The semiconductor device of claim 1, wherein
each of the first active pattern and the second active pattern further includes a center portion between the first edge portion and the second edge portion, and
the center portion of the first active pattern and the center portion of the second active pattern are sequentially arranged in the second direction.

8. The semiconductor device of claim 1, wherein
each of the first active pattern and the second active pattern further includes a center portion between the first edge portion and the second edge portion, and
the semiconductor device further comprising:
a bit line node pad provided on each of the center portions of the first and second active patterns.

9. The semiconductor device of claim 1, further comprising:
a first bit line extending in the third direction on the first active pattern; and
a second bit line extending in the third direction on the second active pattern,
wherein the first storage node contact and the second storage node contact are disposed between the first bit line and the second bit line.

10. The semiconductor device of claim 9, wherein the fence pattern has a rounded corner between the first bit line and the second bit line when viewed in a plan view.

11. The semiconductor device of claim 1, further comprising:
a third active pattern adjacent to the second active pattern in the third direction,
wherein the third active pattern includes a first edge portion and a second edge portion spaced apart from each other in the first direction, and
wherein the second edge portion of the third active pattern is adjacent to the first edge portion of the first active pattern.

12. The semiconductor device of claim 11, further comprising:
a third storage node pad and a third storage node contact sequentially provided on the second edge portion of the third active pattern,
wherein the second storage node contact, the first storage node contact and the third storage node contact are arranged in a line in the third direction.

13. The semiconductor device of claim 11, further comprising:
a dummy word line extending in the second direction between the second active pattern and the third active pattern.

14. A semiconductor device comprising:
a first active pattern and a second active pattern extending in a first direction and adjacent to each other in a second direction, the second direction intersecting the first direction, the first and second active patterns, each including a first edge portion and a second edge portion spaced apart from each other in the first direction;
a pair of word lines extending in the second direction to intersect the first active pattern and the second active pattern;
a first storage node pad and a first storage node contact sequentially provided on the first edge portion of the first active pattern; and
a second storage node pad and a second storage node contact sequentially provided on the second edge portion of the second active pattern,
the first storage node pad including a same material as the first storage node contact.

15. The semiconductor device of claim 14, wherein the first storage node contact includes dopant-doped poly-silicon.

16.-17. (canceled)

18. The semiconductor device of claim 14, wherein each of the first active pattern and the second active pattern further includes a center portion between the pair of word lines, and
the semiconductor device further comprising:
a bit line node pad provided on each of the center portions of the first and second active patterns.

19. The semiconductor device of claim 18, wherein the bit line node pad includes a same material as the first storage node contact.

20. The semiconductor device of claim 19, wherein at least one of the first storage node pad and the bit line node pad further includes a metal material.

21. A semiconductor device comprising:
a first active pattern and a second active pattern extending in a first direction and adjacent to each other in a second direction, the second direction intersecting the first direction, the first and second active patterns, each of including first and second edge portions spaced apart from each other in the first direction and a center portion between the first and second edge portions;
a pair of word lines extending in the second direction to intersect the first active pattern and the second active pattern;
a first storage node pad and a first storage node contact sequentially provided on the first edge portion of the first active pattern;
a second storage node pad and a second storage node contact sequentially provided on the second edge portion of the second active pattern;
a first bit line extending in a third direction, the third direction intersecting the first and second directions, on the first active pattern;
a second bit line extending in the third direction on the second active pattern;
a fence pattern between the first storage node contact and the second storage node contact;
landing pads on the first storage node contact and the second storage node contact; and
data storage patterns on the landing pads,
a bottom surface and a top surface of the first storage node contact located at a first level and a second level, respectively, and
a width of the fence pattern in the third direction at the first level being less than a width of the fence pattern in the third direction at the second level.

22. The semiconductor device of claim 21, wherein
each of the landing pads includes a lower portion and an upper portion, and
the upper portion of each of the landing pads is shifted from the lower portion in the third direction or an opposite direction to the third direction.

23. The semiconductor device of claim 21, further comprising:
a third active pattern adjacent to the second active pattern in the third direction; and
a fourth active pattern adjacent to the first active pattern in the third direction,
wherein
each of the third active pattern and the fourth active pattern includes a first edge portion and a second edge portion spaced apart from each other in the first direction; and
a center portion between the first and second edge portions, and
the first bit line further extends onto the center portion of the fourth active pattern, and
wherein the second bit line further extends onto the center portion of the third active pattern.

24.-28. (canceled)
